(19) United States
(12) Patent Application Publication
(10) Pub. No.: US 2024/0201422 A1
(43) Pub. Date: Jun. 20, 2024

(54) LOW INDEX OF REFRACTION THIN FILM WITH HIGH HARDNESS COATING AND METHOD AND APPARATUS TO PRODUCE SAME

(71) Applicant: INTEVAC, INC., Santa Clara, CA (US)

(72) Inventors: Thomas P. Nolan, Fremont, CA (US); Alexander Vassilievich Demtchouk, Sunnyvale, CA (US); Samuel D. Harkness, IV, El Cerrito, CA (US); Jae Ha Choi, Pleasanton, CA (US)

(21) Appl. No.: 18/391,113

(22) Filed: Dec. 20, 2023

Related U.S. Application Data
(60) Provisional application No. 63/434,048, filed on Dec. 20, 2022.

(51) Int. Cl. G02B 1/14; C23C 14/06; C23C 14/35; G02B 1/11

(52) U.S. Cl. CPC G02B 1/14; C23C 14/0676; C23C 14/352; G02B 1/11

(57) ABSTRACT

A coated article comprising: a transparent substrate and a protective coating comprising: an adhesion layer formed over the substrate; a protective layer formed over the adhesion layer and may have refractive index of from 1.6 to 1.8; and an anti-reflective layer formed over the protective layer, the anti-reflective layer comprises a plurality of sublayers, wherein at least one sublayer has a refractive index higher than index of said protective layer and at least one sublayer has a refractive index lower than the index of said protective layer.

### RELATED APPLICATIONS

This Application relates to and claims priority benefit from U.S. Provisional Application Ser. No. 63/434,048, filed on Dec. 20, 2022, the disclosure of which is incorporated herein in its entirety.

### BACKGROUND

### Field

This Application relates to systems for physical vapor deposition and to control of processes in systems used in physical vapor deposition to form thin film coatings on articles.

### Related Arts

With the huge popularity of mobile devices, such as, cell phones, smart watches, VR goggles and other devices, which have optical displays, there is a growing need to protect these devices from handling damage which degrades their appeal. Transparent panels (glass or plastic) that are used to protect optical displays need to be optically clear, have high transmission, low reflectivity, and be scratch and scuff resistant. The resistance of the panels to scratch and scuff can be enhanced using coatings which does not degrade the optical properties of the panel. Such coatings can be formed using a physical vapor deposition (PVD) process, otherwise known as sputtering.

To make durable scratch resistant optical films, multiple thin layers, <250 nm, and at least one thick layer, >500 nm are desired. The multiple thin layers are used to modify optical properties, such as reducing reflectance, or modify mechanical properties such as Young's modulus.

Batch systems, such as drum coaters, have been used in manufacturing to deposit such multiple layer film structures. They can deposit multiple layers; however, they have several limitations. Since they swing an arc past the deposition sources the substrate size is limited due to uniformity concerns. Also they cannot deposit multiple layers with differing properties simultaneously. For example, a SiON film with an index of 1.65 cannot be deposited in a drum coater while also depositing a SiON film with an index of 1.90 in the same drum coater. There is too much fluid communication between sources which would affect the two layers. Additionally drum coaters vent the process chambers between batches, which can create particles and process variations due to water uptake during the vent and reload process.

Inline coaters use load locks to bring the substrates in and do not have substrate size limitations. However, they have their own limitations. Since the substrates move past the sources in a head to toe arrangement, each layer must have their own dedicated sources. The more layers and the thicker the layers the more sources are required. This results in a large expensive system with a great deal of work-in-progress (WIP) time inside the system as parts wait their turn for each sequential process step. Also process reactant gas isolation is difficult to achieve, since during movement of substrate from one chamber to the next gasses can transfer as well.

Applicant has previously disclosed a system architecture for combined static and pass-by processing. See, U.S. Pat. No. 9,914,994 to Leahey et al. However, such a hybrid deposition system provides several process control challenges not experienced by either traditional in-line systems operating a steady-state process or batch systems with load locks, wherein each layer deposition chamber is isolated before initiation of the sputter process. In the hybrid deposition system, one station may be running a steady state process for thick layer deposition while a connected neighboring station is rapidly changing process flows to switch process conditions for each successive thin layer. The open pass-through design thus results in changing sputter gas flows diffusing back and forth between neighboring deposition chambers that can significantly affect film properties.

There is thus a need in the art for an improved method and apparatus for reactively processing thin films, including design and control so as to simultaneously achieve rapid stable process changes in batch stations and maintain uniform process and properties throughout deposition of thick layers in the inline stations; thereby rapidly and efficiently providing thin-film stacks including novel properties.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide a deposition system, which enables enhanced control of different deposition processes to provide different thin layers of different properties, such as density and hardness. The system is especially beneficial for consecutively depositing different types of thin layers on the substrate to enhance the substrates optical and mechanical properties.

Disclosed aspect include a unique system architecture that combines batch and inline processes with good reactant gas control between layers on one economical system. Magnetrons are used in pairs for sputtering deposition. For thick individual layers multiple pairs are used, while for thin layers single pairs are used. To deposit thin layers the substrate passes multiple times back and forth past the source pair. Each pass can deposit a different thin layer. For example, pass one could deposit a 1.6 refractive index SiON, pass two could deposit a 1.9 index film, pass three could deposit a 1.7 index film and so forth.

To deposit thick layers, multiple pairs of sources may be employed for high throughput deposition. The substrate moves past these sources in an inline method with the substrates or carriers head to toe. Only in the “inline” deposition chamber(s) are the carriers head to toe. In the “batch” chambers there is only one carrier. This greatly reduces the WIP time waiting for the slowest process in a sequential coater to complete processing, thereby significantly increasing deposition efficiency and throughput. This architecture yields the best benefits of a batch system: multiple passes past a source or sources and the best benefits of an inline system with load locks, good uniformity and high productivity.

Disclosed aspects include a coated article comprising: a transparent substrate and a protective coating, the protective coating comprising: an adhesion layer formed over the substrate; a protective layer formed over the adhesion layer and may have refractive index of from 1.6 to 1.8; and an anti-reflective layer formed over the protective layer, the anti-reflective layer comprises a plurality of sublayers, wherein at least one sublayer has a refractive index higher than index of said protective layer and at least one sublayer has a refractive index lower than the index of said protective layer.

Other disclosed aspects include an optical coating film, comprising an oxynitride of a base cation material, the film having refractive index lower than 1.8, hardness greater than 18 GPa, and thickness above 500 nm but below 3 microns. Properties of the optical coating film may be tuned by proper setting of clocking angle, anode aperture, substrate transport speed, gas flow rates and cathode power.

For the production of the protective optical coating, a plasma processing system is disclosed, comprising: a vacuum enclosure having a first station, a second station, and a partition between the first station and the second station, the partition having a permanently open transport port; a first sputtering source positioned in the first station and having a first gas supply; a second sputtering source positioned in the second station and having a second gas supply; a transport track transporting substrates among the first and second stations; and a controller executing plasma processing in the first station and the second station according to preset first station recipe and preset second station recipe, the controller further executing predictive control by changing the preset second station recipe according to gas leakage correction factor. The system may also include a process sensor sending status signal to the controller, and wherein the controller further executes iterative correction to the preset second station recipe according to the status signal. The controller may execute predictive control by changing flow rate in the second station in response to gas flow rate change in the first station, according to the gas leakage correction factor.

Aspects disclosed include a method for operating a plasma processing system by setting first process recipes for first station specifying initial gas flow rate, a change point, and a subsequent gas flow rate; setting second process recipes for second station specifying second gas flow rate; setting an initial estimate for gas leakage from the first station into the second station through the transport opening; and calculating a gas flow change for the second station using the initial gas flow rate and the subsequent gas flow rate of the first station, and the initial estimate; executing plasma processing simultaneously in the first station and the second station according to the first process recipe, the second process recipe and the gas flow change.

Also, aspects include a method comprising: setting first process recipes for the first station specifying first gas flow rates; setting second process recipes for the second station specifying second gas flow rates; setting an initial estimate for gas leakage from the first station into the second station through the transport opening; and energizing the first station to process substrates according to the first process recipe; energizing the second station to process substrates according to the second process recipe; monitoring processing in the first station and whenever the first process recipe specifies a change in the first gas flow rate, modifying the second gas flow rate using the initial estimate.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A schematically depicts a top view of the magnet arrangement with all other parts of the magnetron removed for clarity, according to an embodiment;

FIG. 1B schematically depicts a cross section of the magnetron assembly along line A-A in FIG. 1A, according to an embodiment;

FIG. 1C schematically illustrates a cross section of one cylindrical target with the magnetron inserted therein, according to an embodiment;

FIG. 1D is a schematic illustrating a cross-section of a sputtering chamber having one cylindrical target with one magnetron inserted therein, according to an embodiment, while FIG. 1E is a schematic illustrating a cross-section of a sputtering chamber having one cylindrical target with two magnetrons inserted therein, according to an embodiment;

FIG. 2 schematically illustrates a cross-section of a sputtering chamber having two cylindrical targets, according to an embodiment, while FIG. 2A illustrates a cross-section of an embodiment utilizing two rotating cylindrical targets, and includes reference lines that describe spatial orientation and relationship among the various elements of the chamber;

FIGS. 2B and 2C illustrate an embodiment of a processing station employing an aperture shield;

FIG. 3 schematically illustrate gas injection and grounding port according to an

embodiment;

FIG. 4 schematically illustrates the operation of a grounding port according to an embodiment;

FIG. 5 illustrates a side grounding port according to an embodiment.

FIG. 6 is a schematic illustrating an exploded view of the carrier and the transport mechanism for substrates, according to an embodiment;

FIGS. 7A-7C are schematics illustrating a carrier base and the transport mechanism for substrates, according to an embodiment;

FIGS. 8A-8C are schematics illustrating a top and side views of carrier tray for substrates positioned on top of the carrier base, according to an embodiment;

FIGS. 9A-9C are schematics illustrating a pedestal for substrates to be positioned on the carrier tray with or without an adjuster, which is positioned on top of the carrier base, according to an embodiment.

FIG. 10 is a schematic illustration of a processing system according to an embodiment.

FIG. 11 is a flow chart illustrating a process according to an embodiment that may be executed by a programmed general-purpose computer, a specialty computing machine, an artificial intelligence machine, etc.

FIG. 12 is a cross section schematic of an article of substrate with protective optical coating, according to an embodiment.

### DETAILED DESCRIPTION

Various embodiments will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

Embodiments disclosed herein provide hybrid deposition system for depositing various thin films on substrates in sequence. Such hybrid deposition systems generate several process control challenges not experienced by either traditional in-line systems operating a steady-state process or batch systems with load locks, wherein each layer deposition chamber is isolated before initiation of the sputter process. In the disclosed hybrid deposition system, one station may be running a steady state process for thick layer deposition while a connected neighboring station is rapidly changing process flows to switch process conditions for each successive thin layer.

Disclosed embodiments of the novel physical vapor deposition system may be employed to manufacture a large range of multiple-layer thin-film coatings, from a few nanometers up to several microns thick, in high-volume at low cost, as well as a novel methods to apply such a system to produce highly transparent hard overcoats with highly tunable optical and mechanical properties. This combination of novel system design and novel processing methods enables novel material properties within well-known material sets that have not been available for high volume processing in the art. The following embodiments of the invention are selected to exemplify key features of the invention but in no way limit the tools, design features or applications where alternative embodiments of the invention may be employed.

Thus, the inventors recognized that novel film properties of films having high deposition rate, extremely high hardness and high index uniformity can be achieved by combining the novel deposition characteristics of a high power, high confinement plasma that enables high-rate oxide and nitride deposition at high voltage without target poisoning. The fabrication of such films is further enabled by filtering of low energy regions by optimized selection of aperture designs and clocking angle, as will be explained in more details below.

The inventors also recognized that a broad range of novel single layer, graded layer and multiple layer structures are enabled by the disclosed system. Some examples of novel material properties that can be rapidly manufactured include: a relatively low index SiOxNy (below n=1.8) having nano-hardness higher than 20GPa; an SiO2 layer having index reduced to n=1.35 for improved optical properties in some applications; and a synthetic multilayer that maintains hardness while relieving stress and increasing toughness by modulating film density. Examples of fabrication of such films will be provided below.

The open pass-through design results in changing sputter gas flows diffusing back and forth between neighboring deposition chambers that can significantly affect film properties. Therefore, an improved method and apparatus for process control is provided to simultaneously achieve rapid stable process changes in batch stations and maintain uniform process and properties throughout deposition of thick layers in the inline stations.

The subject inventors recognized that purely reactive iterative process controls can be insufficient to maintain uniform process and properties of films being simultaneously deposited in multiple stations, while rapid process changes are being applied in one or more of the stations. Therefore, the inventors have developed a novel adaptive process control method and apparatus to combine reactive controls with predictive controls developed using feedback from multiple sensors during offline as well as in process machine learning. Some embodiments enable optimally rapid, stable transitions of process parameters including reactive and carrier gas flows at different locations within each station, as well as power, so as to minimize WIP delay between sputter of successive layers in a station. Further embodiments enable predictive simultaneous corrections to process parameters in all stations that assist reactive corrections in maintaining a stable uniform process for deposited films in all stations. Yet further embodiments enable reactive and predictive corrections to process parameters in response to gradual long-term changes such as vacuum degradation, machine aging or target erosion, that may require changes to the gas flow balance between different target locations as well as total gas flow requirements. The embodiments disclosed below are selected to elaborate and exemplify key features of the invention but in no way limit geometries, tools, design features or applications where alternative embodiments of the invention may be employed.

The disclosed method and apparatus is described herein in a hybrid sputtering process system, which employs paired sputtering sources. The disclosure first explains embodiments of the sputtering sources and their various features, stations employing paired-sputtering sources, and a system having multiple sputtering stations. Also, examples for methods of operating and controlling the system and processes of forming thin-film fabrication are also described.

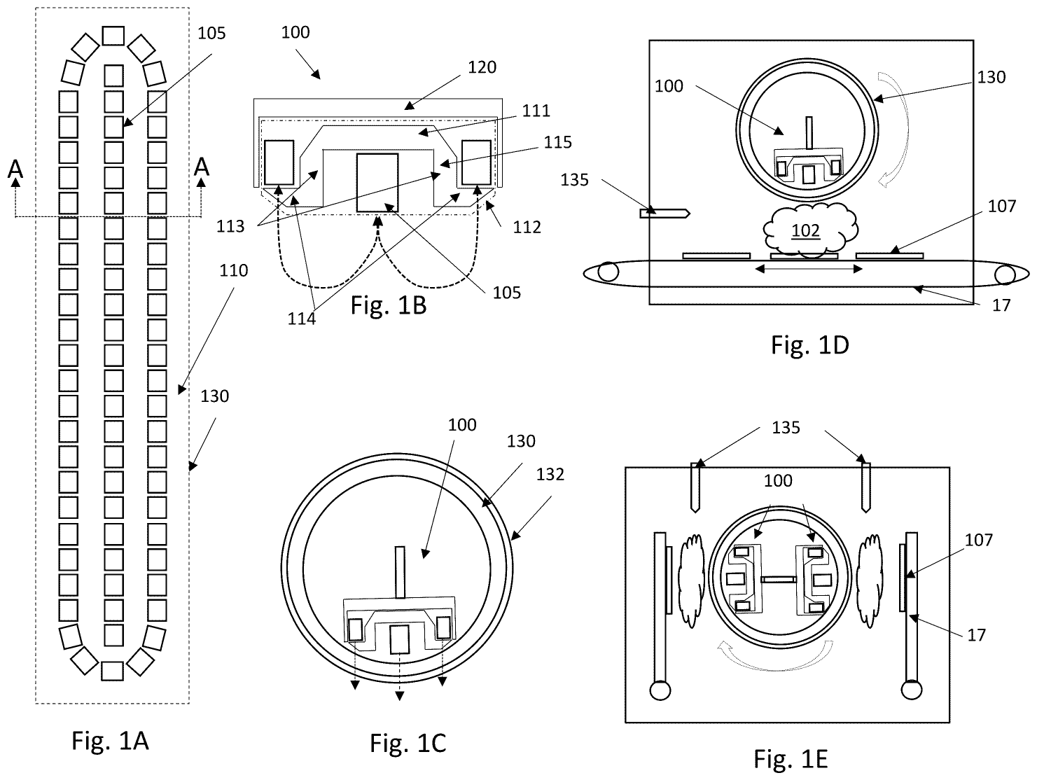

FIG. 1A schematically illustrates the arrangement of a first set of magnets and a second set of magnets, in a top view. The first set of magnets 105 is arrange on a straight line, with all of the magnets of the first set are oriented with the same polarity. The second set of magnets 110 is arranged with the magnets in an obround shape, colloquially sometimes referred to as race-track shape, around the first set 105. Incidentally, an obround shape is a shape having the form of a flattened cylinder with the sides parallel and the ends hemispherical, i.e., the magnets are arranged as two parallel line segments connected at each end with a semicircle. Stated another way, it is a plane shape consisting of two semicircles connected by parallel line segments tangent to their endpoints. All of the magnets of the second set 110 are oriented in the same polarity, which is opposite that of the magnets of the first set. For example, if the side of the magnets of the first set shown in the drawing (facing the reader) is the north pole (with their south pole facing away from the reader, or into the page), then the side of the magnets of the second set as shown in the drawing is the south pole (with their north pole facing away from the reader, or into the page).

FIG. 1B illustrates a cross section of an embodiment of the magnet arrangement, generally referred to herein as magbar, along line A-A of FIG. 1A. As shown in the orientation of FIG. 1B, and generally as referred to within this disclosure, a reference to a “down” or “front” direction would mean direction facing the target and the plasma (see FIG. 1C), while reference to “up” or “rear” direction would be facing away from the target and the plasma. As shown in FIG. 1B, keeper plate 115 is interposed between the magnets of the first set and the magnets of the second set, such that magnetic field lines (see dashed curved arrows) emanating from magnets of the first set must pass through the keeper plate in order to reach magnets of the second set. Stated another way, a straight line (see dotted arrows FIG. 1C) passing through the axis of a magnet from the second set (i.e., passing through both poles of the magnet) must intercept the keeper plate before it can reach the interior wall of the target, while a straight line (see dashed arrow) passing though the axis of magnets of the first set can reach the interior wall without crossing the keeper plate. The keeper plate is a magnetically permeable obround shaped plate that helps shape the magnetic flux over the target surface. The plate shunts the magnetic field.

The obround shaped keeper plate may have a cross-section resembling a trough of a U-shape with outwardly angled extensions at each end of the U-shape opposing the valley. The U-shaped trough is formed of a flat base 111, two parallel risers 113 extending from opposing edges of the base 111, and two outwardly angled extensions 114 extending in opposite direction from each other from the ends of the risers 113. The magnets of the first set of magnets are arranged within the valley of the U-shape on one side (or in front of) of the shaped keeper plate, while the magnets of the second set are arranged on the opposite side (or in the rear of) the shaped keeper plate, nestled in area bound by the risers 113, the extension 114 and the cover 120. Thus, when the magbar is installed within a sputtering target, the magnets of the first set have unobstructed direct line of sight to the target, while the magnets of the second set are obstructed from direct line of sight to the target by the keeper plate.

As noted, a cover 120 is provided around the second set of magnets, thereby encasing the magnets of the second set between the cover 120 and the keeper plate 115. That is, the magnets of the second set of magnets are housed within a space defined between the cover 120 and the keeper plate 115. The entire assembly of magnets and keeper plate shown in FIG. 1B may optionally be encapsulated within insulating material 112 (shown in dash-dot lines), such as, e.g., resin.

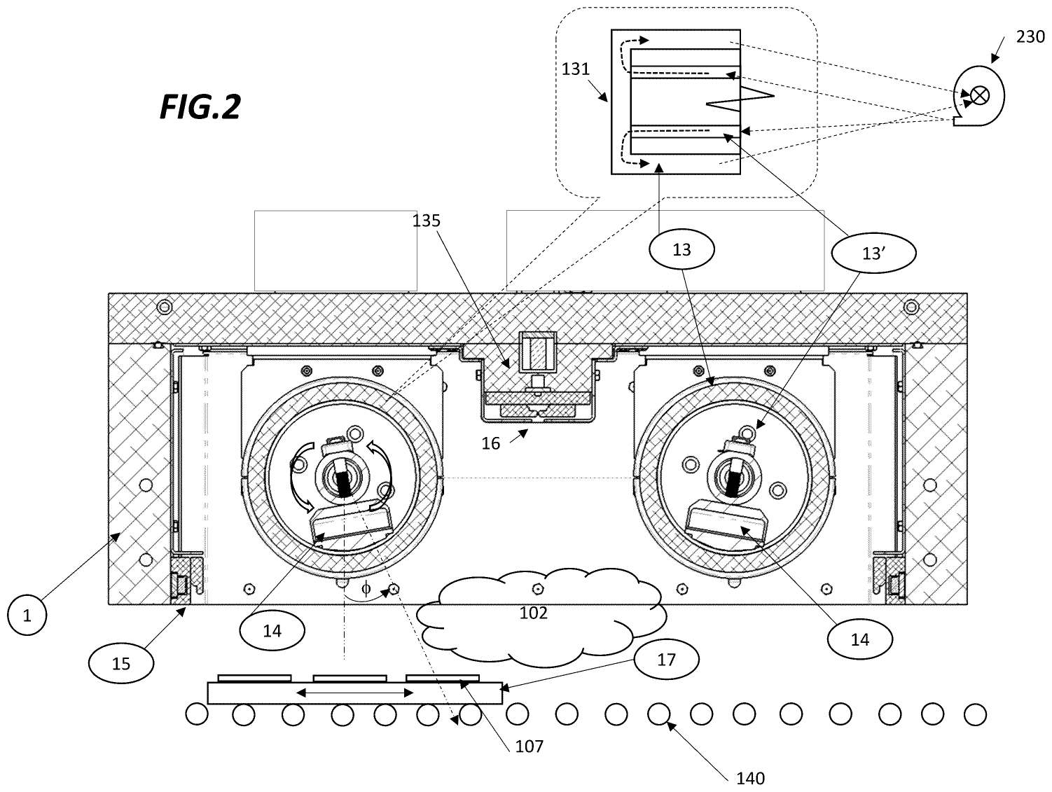

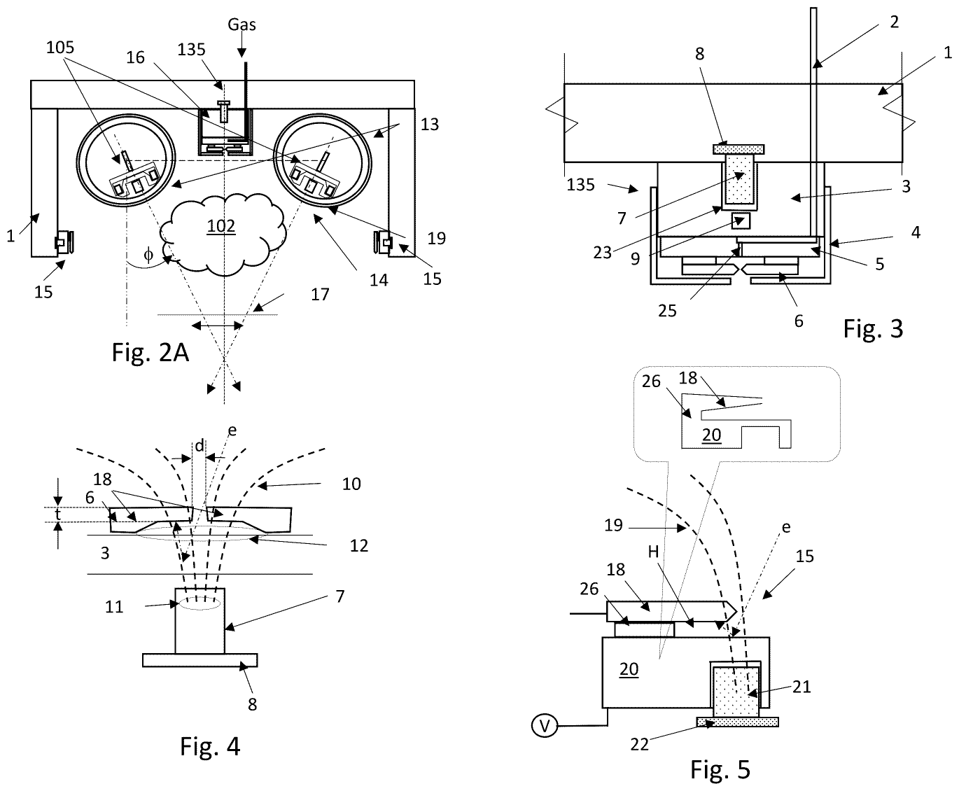

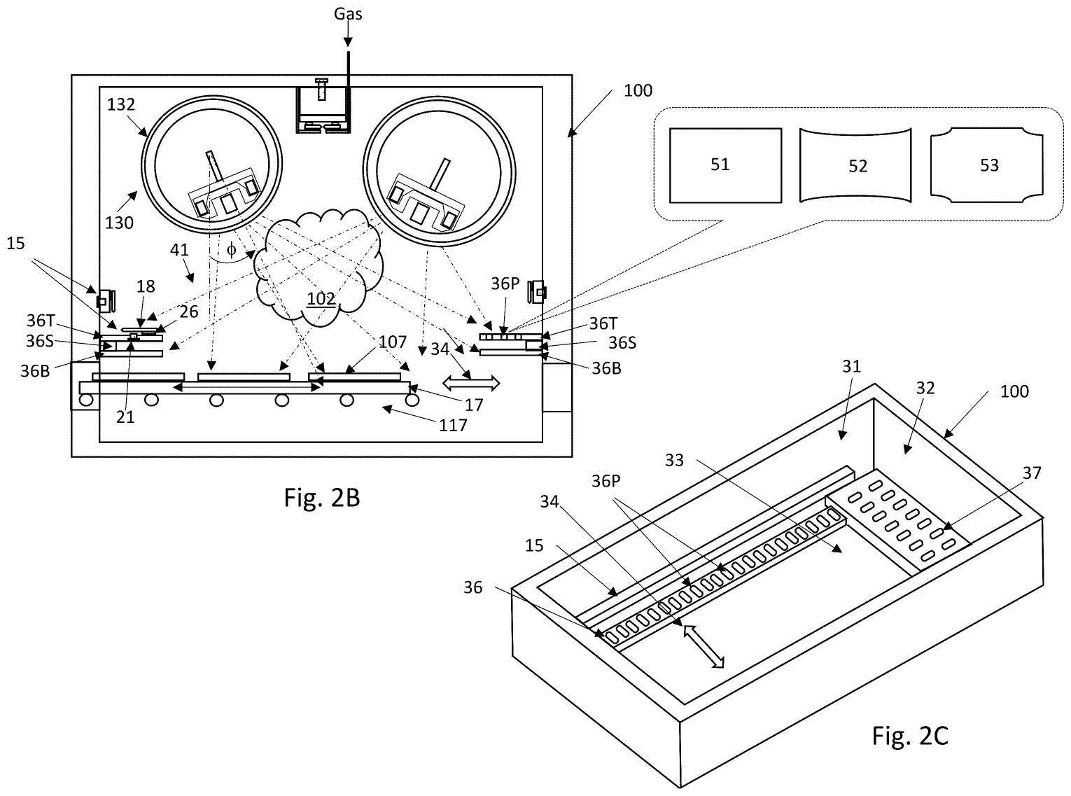

FIG. 1C is a schematic cross-section illustrating the magbar 100 installed inside the rotating cylindrical target 130. The cylindrical target 130 is coated with a sputtering layer 132 made of the material to be sputtered onto a part to be coated, e.g., SiAl for coating a glass plate. That is, sputtering layer 132 is consumed during the sputtering operation. In operation, magbar 100 is held stationary while the cylindrical target 130 rotates about its axis (perpendicular to the page), so that the area of the target from which plasma sputtering of material is performed changes with the rotation of the target. Consequently, the material of the target is consumed evenly from the entire circumference of the target. In this respect, while the magbar 100 is held stationary during a process cycle, its orientation can be changes about its axis. That is, the angle that the magnets are held with respect to the vertical, which may also be referred to herein as the clocking angle, can be changed for different processes. This feature will be explained in further details below with reference to FIGS. 2A-2C.

FIG. 1D illustrates a cross-section of a sputtering chamber according to an embodiment, which utilizes a single rotating target 130. The chamber has a vacuum enclosure that may be rectangular with openings to introduce substrates in a travel direction (see double headed arrow in FIG. 1D), while the cylindrical target extends in a transverse direction which is orthogonal to the travel direction (into the page in FIG. 1D). In examples, the cylindrical target may extend for, e.g., one meter in the transverse direction, i.e., into the page.

In this example, the substrates 107 to be coated are transported on conveyor belt 17 below the target 130. The plasma 102 is confined to the area between the target and the substrate by the specific design of the magbar 100, as disclosed herein. If provisions to hold the substrate in place are provided, e.g., clips, the entire page can be held upside-down to illustrate an embodiment wherein the target is positioned below the substrates and sputtering occurs upwards. This can be done, for example, to cause any unwanted particles to be pulled downwards by gravity and avoid landing on the substrates and contaminate them.

In FIG. 1D gas injector 135 is provided to inject reactive gas, such as oxygen and/or nitrogen, that would react with the material sputtered from the target to change its composition. Also, non-reactive gas, such as argon can be injected to sustain plasma and to sputter the sputtering material 132 from the target. Thus, if the target is made of, e.g., SiAl, and the gas injected includes argon, oxygen and nitrogen, the argon species would dislodge SiAl particles from the target, which would react with the oxygen and nitrogen, so that the material deposited on the substrates would be SiAlON.

FIG. 1E illustrates an embodiment wherein two magbars 100 are placed inside a cylindrical rotating target, oriented at 1800 and pointing away from each other, thus maintaining plasma sputtering over two areas of the target simultaneously. In this embodiment the substrates 107 are held vertically by carriers 17 and move in a direction in-out of the page. Injectors 135 inject gas to the space between the target and the substrates so as to interact with the material being sputtered from the target.

With the above disclosure, a sputtering system is provided, comprising: a cylindrical target having sputtering material on exterior surface thereof; a magnet arrangement provided inside the cylindrical target, the magnet arrangement comprising a first set of magnets arranged on a single straight row, each magnet of the first set having a first pole facing interior wall of the cylindrical target and a second pole facing away from the interior wall, a second set of magnets arranged in a race-track shape around the first set, each magnet of the second set having the first pole facing away from the interior wall of the cylindrical target and the second pole facing the interior wall; a keeper plate positioned between the first set of magnets and the second set of magnets, such that a straight line passing through an axis of a magnet from the second set intercepts the keeper plate prior to reaching the interior wall, while a straight line passing through an axis of a magnet from the first set reaches the interior wall without having to intercept the keeper plate; and a cover enclosing the second set of magnets between the cover and the keeper plate. The keeper plate may have a cross-section resembling a U-shape with angled extensions at each end of the U-shape opposing the valley.

FIG. 2 illustrates an embodiment for sputtering station that utilizes two rotating targets in tandem, so as to sustain plasma in between the cathodes and sputter material from both targets concurrently. The entire arrangement shown in FIG. 2 may be placed inside a vacuum chamber to form a sputtering station in a sputtering chamber. The magbars inside the two targets may be oriented so that their axes are vertical and parallel with each other. Alternatively, the magbars 14 may be angled away, or as illustrated in FIG. 2, towards each other. For example, in each target the magbar 14 can be oriented away from the vertical at an angle ϕ of, e.g., about 15-60 degrees, e.g., 30 degrees, towards the twin target, as shown by the arrows and clocking angle ϕ on the left target. In this way, plasma 102 is maintained in an area between the twin targets 14 to thereby sputter material from both targets concurrently. Additionally, in this embodiment gas injector assembly 16 is positioned between the twin targets so as to inject gas in between the two targets and towards the plasma, so that the gas species is consumed by material sputtered from both targets.

Particularly, it is found in some embodiments of the chamber that, for a vertical position of the magbar (clocking angle=0), material deposited directly below each cathode has a very high average adatom energy and correspondingly films deposited there have very high density, hardness and stress. SiNy films deposited at those locations can be fully dense, having n=2.05, hardness over 25 GPa and compressive film stress over 1 GPa. At the same time, a film deposited at an angle ϕ of about −60 degrees to the side of the cathode, at the entrance to the sputter chamber adjacent to a transverse anode has much lower adatom energy and may have low density, refractive index n<1.8, and very low compressive stress. In some embodiments, deposition at the center-line of the chamber, half way between the cathode axes, also has lower adatom energy and refractive index than that directly below each cathode.

In contrast, a magbar clocking angle ϕ such as +30 degrees toward the center-line of the chamber provides uniform fully dense SiNy films having n=2.05 from each cathode to the centerline of the chamber. However, the low index deposition near the entrance to the sputter chamber adjacent to a transverse anode spans a larger area. Negative magbar clocking angle such as −30 degrees (away from the center-line of the chamber) provides more fully dense SiNy films near the entrance to the sputter chamber but produces n<1.8 films that span a larger area near the chamber centerline.

Thus, by changing the clocking angle ϕ between different process periods, different films, having different properties, can be deposited. The use of different clocking angles in conjunction with different anode aperture, as will be explained more fully below.

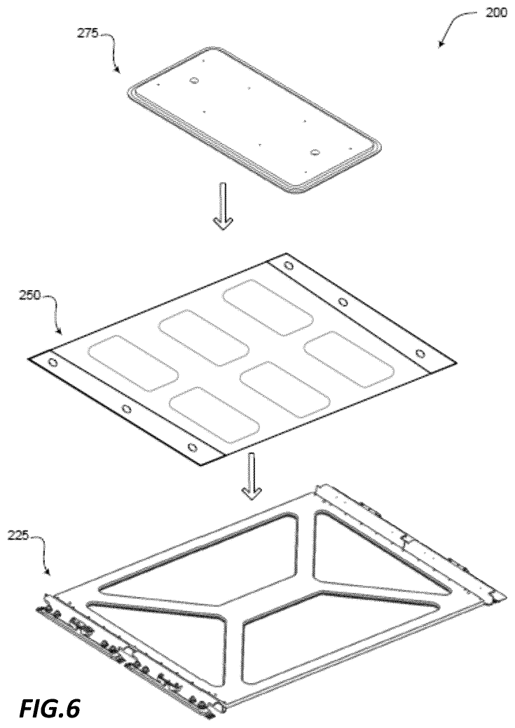

Additional features shown in FIG. 2, include grounding arrangement 15 (see also FIG. 5) and target cooling arrangement. The cooling arrangement includes fluid delivery pipes 13′ which deliver cooling fluid inside the target towards an end-wall of the target (see callout in FIG. 2, which shows a section of the cylindrical target in cross-section along the target's length). The pipes 13′ terminate at a given prescribed distance from the end-wall and have an open end. Consequently, the fluid emanating from the pipes 13′ hit the end-wall 131 and deflect back towards the fluid return sleeve 13, where it flows in the opposite direction from the flow in the pipes 13′, as illustrated by the dotted arrows. As the fluid flow in the return sleeve 13 it cools the target. It is then collected at the other end (obscure in FIG. 2) and sent to a chiller 230 prior to being reflowed in pipes 13′.

FIG. 2 also illustrates a transport mechanism wherein magnetic wheels 140 are used to transport tray 17 upon which multiple substrates are placed. Embodiments of the transport mechanism will be discussed in more details below with reference to FIGS. 6-9.

A typical use of the above-mentioned setup is to convert a material from the target's stoichiometry to a film comprising an adjusted oxidation state (compared to the original material). Such films generally become dielectric and often present opportunities in the fields of optics, tribology and diffusion to name a few. The most common practice involves introduction of reactive gases (e.g., O, N, H, etc.) during processing that ultimately form the desired bonding and resultant stoichiometry in the film, e.g., SiAlON. This process will often produce an excessive amount of electrons that may cause deleterious plasma damage and heating effects and thereby inhibit film quality. One remedy utilizes an engineered anode to collect the excessive flux and thereby remove it from possible film interaction. However, the adsorbate typically insulates all surfaces on the interior of the chamber and the anode is no exception. Therefore, the plasma tends to become unstable as the anode “disappears”, i.e., it's electrical potential with respect to the plasma is insulated by oxidation material build-up so that from the perspective of charged particles within the plasma, it doesn't exist.

FIG. 2A illustrates a cross-section of an embodiment utilizing two rotating cylindrical targets, and includes reference lines that describe spatial orientation and relationship among the various elements of the chamber. As illustrated, the two magnetrons 105 within the cylindrical targets are tilted towards one another, e.g., at clocking angle of 30°, such that plasma 102 is maintained between the two cathodes 13. Generally, the magnetrons may be oriented vertically, as shown by the dash-two-dots line, i.e., with its axis of symmetry orthogonal to the floor of the chamber, or be tilted at a clocking angle o from the vertical, as in FIG. 2A. Clocking angle ϕ may be set at, for example, 0°-60° from the vertical, e.g., −300, 0°, +30° from the vertical, wherein negative clocking angle means that the magnetrons are tilted away from each other, and positive clocking angle means that they are tilted towards each other.

Each of the magnetrons defines an axis of symmetry that passes through its center, represented in FIG. 2A by the dash-dot arrows. When the targets are tilted at a positive clocking angle the axes of symmetry of the two magnetrons cross each other at a point ahead of the surfaces of the rotating targets. When the two rotating targets are positioned horizontally, i.e., a straight line passing through their axis of rotation is horizontal line (see wide-dash line), and with positive clocking angle the two axes of symmetry cross each other at a crossing point below the horizontal line. Additionally, a straight line connecting the crossing point and the center of gas injection assembly 135 is perpendicular to the horizontal line (see dotted line in FIG. 2A).

As noted, the ability to fabricate thin layers of properties is assisted by the structure and ability to change the clocking angle of the magnetrons, the use of paired cylindrical targets, the ability to efficiently remove electrons (explained below with reference to FIGS. 3-5), and the provision of a station aperture that limits the cone of particles that may reach the substrate, thus filtering the approach angle of the particles landing on the substrate. The later feature will not be described with reference to FIGS. 2B and 2C.

FIG. 2C schematically illustrates a cross-section of a plasma chamber constructed for vacuum processing in the form of physical vapor deposition, having anode aperture shield according to disclosed embodiments. In this embodiment, a pair of sputtering target 130 is mounted close to the ceiling and situated within the vacuum chamber 100, but other sputtering targets may be utilized, e.g., rotating or stationary and attached to the ceiling or sidewall. Also, generally vacuum chamber 100 may be circular, rectangular, square, etc., while for simplicity the disclosed embodiments illustrate rectangular vacuum chamber 100. The magnetrons 105 are positioned inside the targets 130 and ignites and maintains plasma 102 over a front surface of the targets 130, such that deposition material 132 of targets 130 is bombarded by species from the plasma 102. Particles from deposition material 132 of the targets 130 are then sputtered off the target and land on the substrates 107 to form a coating. Here, as an example, the substates travel on a carrier 17, which rides on wheels or transport tracks 117, but the substrate may be stationary or in motion, e.g., on a conveyor, during the sputtering process.

The particles sputtered from deposition material 132 may travel at different angles as they approach substrates 107, as shown by the dash-dot arrows. Film formed on the substrates from particles landing at different approach angles have different optical and physical characteristics. Therefore, in disclosed embodiments an aperture is formed using grounded anodes, that limits the line of sight to substrates available to particles sputtered towards the substrates. The aperture and its different variations will be described below with reference to FIGS. 2B and 2C.

FIG. 2C illustrates a schematic open-top view of the geometry of a pass-through deposition chamber 100 including one embodiment of a ground anode aperture. Chamber 100 includes transverse chamber walls 31 along a transverse axis, transport chamber walls 32 along a transport axis 34 (double-headed arrow), wherein a transport carrier 17 traverses the chamber 100 along a transport axis 34 (FIG. 2B). The ground anode aperture is formed by two transverse aperture shields 36, each attached to one transverse chamber wall 31, and two transport aperture shields 37, each attached to one transport chamber wall 32. The transverse and transport shields traversing all four walls together comprise an aperture shield that defines aperture 33, which limits line of sight to the substrates from the target, and is roughly rectangular in the embodiment illustrated in FIG. 2C. This aperture shield blocks shallow angle, low energy plasma deposition that produces unwanted low-density deposition around the edges of the chamber, as shown by the dash-dot arrows illustrated in FIG. 2B. The shallow angle deposition path 41, e.g., larger than 300, 45° or 60° from the vertical to the substrate, is blocked from depositing film onto carrier 17 by transverse anode shield, allowing only normal and steep angle deposition, thereby increasing the film density and uniformity of a film deposited on substrates 107 crossing the location indicated by the arrow 33 as it passes through the chamber 100.

A previously discussed, the average adatom energy and corresponding film density and other properties may not be uniform across the carrier along the transverse axis. In some embodiments, lateral nonuniformity may be compensated by designing a non-rectangular aperture shield as illustrated in the callout of FIG. 2B. Rectangular aperture 51 provides a constant transport path length of enabled deposition across the transverse axis of the carrier. Convex aperture 52 provides an increasingly longer transport path length of enabled deposition across the transverse axis of the carrier. Such an aperture allows less high angle sputter along the transport direction at the center of the transverse axis, that can compensate for the increased high angle sputter owing to receiving more high angle lateral sputter from both sides along the transverse axis. Edge notched aperture 53 is an appropriate design to compensate fast edge deposition along an erosion groove that commonly forms at each end of a cathode for pass-by deposition owing to magnetic flux closure required at each end.

Referring back to FIG. 2B, the shields, especially the two transverse aperture shields 36 may be constructed in various designs, two of which are shown in FIG. 2B. In each of these designs, the aperture shield is constructed out of a top plate 36T, a bottom plate 36B, and an optional spacer positioned therebetween 36S. In some embodiments the spacer 36S may include a magnet array embedded therein. At least one of the top plate 36T and bottom plate 36B is conductive and coupled to ground, e.g., by being mounted onto the grounded sidewall of chamber 100. The aperture plates may be fabricated out of Al, Cu or Fe-based materials, e.g., stainless steel. In embodiments the top plate 36T includes perforations 36P. According to another embodiment the top plate 36T of the transverse shield 36 incorporates a grounding anode 15. The structure and function of the anode 15 will be described more fully below with reference to FIGS. 4 and 5.

In operation, plasma is ignited and maintained by injecting precursor gas from injector assembly 135, which in this example also acts as anode, as will be explained with reference to FIG. 4. The flux is generated under classical magnetron dynamics wherein the magnetically confined region defined by the magnetrons 105 enable efficient ionization of gas species such as Ar, Kr, Xe, Ne, He, etc., which subsequently become accelerated toward the cathode held at potential (e.g., −400 V or larger). The impact of these accelerated species imparts sufficient energy to dislodge previously bonded material 132 of the target 130 into the vacuum space where they then become available for deposition on the substrates 107. The targets 130 are made of material 132 that ultimately deposit on the intended substrates 107 with identical stoichiometry. Conversely, the injector assembly 135 may additionally injects reactive gas, such oxygen and/or nitrogen, which would react with the sputtered species, so that the layer formed on the substrates 107 incorporates reacted species.

An important issue in maintaining stable plasma to result in uniform film is the removal of excess electron by consistently presenting to the electron clear path to ground. The disclosure turns to novel features that efficiently accomplishes maintaining clear path to ground.

FIG. 3 is a schematic showing the features comprising the novel approach to a centralized anode incorporated within the gas injection assembly 135. It should be noted that while in FIG. 1D the gas injection assembly is shown on one sidewall of the chamber, it may actually be placed anywhere that is appropriate for gas injection, e.g., on the ceiling, as shown in FIG. 2. Also, when deployed between two cylindrical rotating targets as shown in FIG. 2, the elements of the centralized anode of FIG. 3 (e.g., anode block 3, magnet array 7, keeper plate 8, gas distribution plate 5, and filters 6 described below) may extend to the length of the cylindrical target (i.e., into the paper as shown in FIG. 2).

As shown in FIG. 3, an anode block 3 is affixed to the chamber wall 1 (or to the ceiling, FIG. 2). The anode block 3 is most appropriately metallic, e.g., aluminum or copper, or otherwise conductive material (both electrical and thermal conductivity). A magnet 7 is mounted on a keeper plate 8, which also affixes directly to the chamber wall 3 and extends into a cavity 23 within anode block 3, such that when at vacuum, there is no connective material making lateral electrical or thermal connection from the magnet 7 directly to the anode block 3. This design criteria is beneficial to inhibiting current flow directly through the magnet structure and preserves thermal stability of the magnet.

Cooling channels 9 are cut into the anode block 3 to allow coolant flow therein to control the temperature of the anode block 3. Additionally, gas delivery line 2 passes through the anode block and provides gas to at least one gas injection orifice 25. The one or more gas injection orifices are provided on a gas distribution plate 5 (also conductive material) that is attached to the top of the anode block 3 and is connected to the gas delivery line 2 to facilitate gas orifice 25 delivery of prescribed gas species to the vacuum environment. Drilled orifices of gas injector 25 are less than 2 mm and more preferably below 1.6 mm in diameter. Such specifications inhibit plasma formation within the plate 5 regardless of the possible electrical potential (as per Paschen's Law). Consequently, less secondary electron generation and consequently lower plasma density forms in the region surrounding the orifice. Also, the at least one orifice is collinear with the highest density of magnet field lines from the magnet 7.

FIG. 4 demonstrates the spatial relationship for the structure of electron filter 6. This filter 6 consists of two filter bars 18 facing each other with a gap therebetween, marked as d. The filter 6 features dimensions that promote the separation of electrons following magnetic field lines from adsorbate particles following line-of-sight trajectories. Specifically, the overall thickness t of the free-standing end of the filter bar is larger, and preferably twice as thick as the distance d separating nearest edge of the mirroring filter bars 18 across the centerline of the anode structure. In embodiments the thickness t is greater than 3 millimeters and may even be greater than 5 millimeters. This collimation optimizes the competing effects of filtering and total capture of electrons. Also, the free-standing end of the filter bar is beneficially thinner than the opposite end that is attached to the anode block, thus defining a hollow area between the anode block and the filter bars.

FIG. 4 illustrates the electron mirroring benefit to ground capture. Magnetic field lines (dashed curves) 10 connect cathode arrays to the center of the anode. A region 11 (dotted oval) shows the densification of field lines as they approach the anode magnet 7. The increase in field intensity, B, causes the reflection of inbound electrons e. The likelihood of momentum transfer causes the electron to reverse course at an angle to the incidence, see dash-dot arrow marked e. As such the collection of reflected trajectories forms a loss cone that is wider than the aperture that admitted the electrons into the anode filter structure. This is represented as dotted oval 12 in FIG. 4, within the hollow space defined between the anode block 3 (or the gas distribution plate 5 if used) and the filter bars 6. The loss reflection allows electrons to then impact on fresh conductive interior surfaces of the filter bars 6, that provide ultimately a pathway to ground. In this way, the anode is kept viable regardless of coating action in the body of the chamber. That is, even if the front surface (i.e., plasma facing surface) of filter 6 gets coated with insulative material, the interior surface (i.e., surfaces hidden from the plasma) would remain exposed and therefore viable conductive pathway to ground.

Reverting to FIG. 3, this set of phenomena reduces the chance for insulating material such as oxides or nitrides to form atop the conductive metal surface of plate 5 or other local structures, such as the electron filter 6. This optimizes the anode structure for durable performance over extended campaign times. To facilitate the rigors of manufacturing, a consumable or sacrificial shield 4 attaches to the outer portion of the anode block 3, where accumulated material clings to further protect the anode from deposition of insulative material.

Another embodiment of an anode 15 is shown positioned on the sidewall of the chamber, peripherally of the cathodes 13 and detailed in FIG. 5. A peripheral anode block 20 is attached to the chamber wall 100. Instead of a dual filter structure as shown in FIG. 3, only half such an assembly is required since only one cathode's field lines 19 are connecting to the peripheral anode 15. Filter bar 18 is attached to the anode block 20, set off by spacer 26, to thereby form a peninsula connected to the anode block at its isthmus, and defining hollowed area H between the filter bar 18 and the anode block 20. In this respect, it can be said that the filter bar 18 is cantilevered off of spacer 26. Also, as illustrated in the callout, in any of the disclose embodiments, the anode block 20, spacer 26 and filter bar 18 may be made integrally as a single block having the cavity for the magnet in the rear and the cantilevered filter bar in the front. In any of the disclosed embodiments the free end of the filter bar 18 may be thinner than the attachment end which is attached to the anode block, or the entire filter bar 18 may be tapered towards its free end, as shown in the callout.

Magnet 21 is inserted into cavity in the anode block and is attached to keeper plate 22, wherein no part of the magnet 21 or keeper plate 22 physically contacts the anode block 20, such that a vacuum break is formed between the magnet 21 and keeper plate 22 and the anode block 20. The filter bar 18 is positioned so as to partially cross the magnetic lines emanating from magnet 21, so that some of the magnetic field lines cross the filter bar 18 and some field lines do not cross filter bar 18. Consequently, electrons deflected by the magnetic field would impact the interior surface of the filter bar 18 that faces away from the plasma, and thus remains uncoated by insulating species.

In any of the disclosed embodiments, the anode block may be electrically connected to the chamber body and be at the same potential as the chamber body, e.g., ground potential. Conversely, as exemplified in FIG. 5, the anode block may be insulated from the chamber body and be connected individually to a potential source V, or the filter bar may be connected to the potential source V. Also, in any of the disclosed embodiments, the magnet has a strength greater than 30 MGOe (mega-gauss-oersted). In any of the disclosed embodiments, the magnetic mirror ratio (r=B(max)/B(min), where B is the magnetic field intensity) is greater than 10 and more preferably greater than 100. In this respect, magnetic mirror refers to the configuration of magnets within the anodes and cathodes to create an area with an increasing density of magnetic field lines at either end of a confinement volume. In the disclosed embodiments the end of interest is at the anode. Particles approaching the ends experience an increasing force that eventually causes them to reverse direction and return to the confinement area. This mirror effect will occur only for particles within a limited range of velocities and angles of approach, while those outside the limits will escape. In the context of the disclosed embodiments, electrons would be deflected to reverse direction and hit the interior side of the electron filter, which is not exposed to insulative coating, thus ensuring clear path to ground for removal of electrons from the plasma.

Reverting to FIGS. 2B and 2C, in embodiments the transverse aperture shield 36 may include an anode 15 with electron filter incorporated therewith. As an example, in the left side of the chamber 100 of FIG. 2B, anode 15 is incorporated into the aperture shield's top plate 36T; however, both transverse aperture shields may incorporate anode 15. In this particular example, the top plate 36T serves as the anode block and the magnet and keeper plate are mounted onto the top plate. The filter bar 18 and spacer 26 are mounted on the top surface, i.e., the surface facing the plasma 102, of the aperture plate. As noted, generally the aperture shields are attached to the sidewall below the cathode but above an opening through which the substrates are delivered into the chamber, so that the anode 15 may form proper magnetic field lines to the cathode. This structure helps removed electrons by presenting consistent path to ground.

With the above disclosure, a sputtering station is provided, comprising: a chamber enclosure having a ceiling; a gas injector assembly positioned to deliver processing gas into the chamber enclosure; a grounding anode mounted onto the enclosure wall; and at least one cathode assembly, the cathode assembly comprising a rotatable cylindrical target having sputtering material on exterior surface thereof; a magnet arrangements positioned inside the cylindrical target in a fixed-non rotating orientation, the magnet arrangement including a first set of magnets arrange on a straight line, wherein all of the magnets of the first set are oriented at same polarity, and a second set of magnets arranged in an obround shape, wherein all of the magnets of the second set are oriented at same polarity opposite polarity of the first set of magnets; a keeper plate interposed between the first set of magnets and the second set of magnets wherein the first set of magnets is positioned against one surface of the keeper plate and the second set of magnets is positioned against an opposite surface of the keeper plate, such that magnetic field lines emanating from the first set of magnets pass through the keeper plate in order to reach the second set of magnets.

The sputtering station may further comprise a plurality of cooling pipes having receiving end coupled to a chiller and at the opposite side an open end terminating a prescribed distance from an end-wall of the target, the target further comprising a return sleeve situated inwardly of the sputtering material, such that cooling fluid flowing in the cooling pipe exit the open end to space between the open end of the cooling pipes and the end-wall, and thence flow into the return sleeve.

The disclosed embodiments provide a deposition system comprising: a vacuum enclosure having sidewalls and ceiling, two sputtering targets positioned inside the vacuum enclosure and defining a plasma area therebetween, each of the sputtering targets having a front surface coated with sputtering material and a back surface, the front surface facing the plasma area; two magnetrons, each positioned behind the back surface of a corresponding one of the two targets; a gas injector mounted onto the ceiling and positioned centrally between the two targets; and a central anode mounted onto the ceiling and positioned centrally between the two targets, the central anode having an anode block and a magnet positioned within the anode block; wherein the two targets, the two magnetrons, and the anode confine plasma within the plasma area to have a slope of log(I) vs. log(V) greater than at least 3 or greater than 4. In embodiments the deposition system further comprises two peripheral anodes, each mounted onto the sidewall and positioned next to a corresponding one of the two targets, each of the peripheral anode comprising an anode block having a cavity, a magnet positioned within the cavity and generating magnetic field lines, and a cantilevered filter bar intercepting at least partially the magnetic field lines.

Also disclosed is a plasma chamber comprising a vacuum enclosure housing a target having a front surface facing a plasma region within the vacuum enclosure and a rear surface facing away from the plasma region, the front surface being coated with sputtering material; a magnetron positioned behind the rear surface igniting the plasma and confining the plasma to the plasma region; an anode position inside the vacuum enclosure and incorporating an electron filter having exposed surface facing the plasma region and a hidden surface facing away from the plasma region, the electron filter generating a mirroring effect to deflect electrons onto the hidden surface. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

Aspect of the disclosed invention include a plasma chamber comprising: a vacuum enclosure having sidewalls and a ceiling, the sidewalls having opening for substrates transport into the vacuum enclosure, a target housed within the vacuum enclosure and having a front surface facing a plasma region within the vacuum enclosure and a rear surface facing away from the plasma region, the front surface being coated with sputtering material; a magnetron positioned behind the rear surface igniting the plasma and confining the plasma to the plasma region; an aperture shield attached to the sidewalls at an elevation below the front surface of the target and above the opening, the aperture shield extending from the sidewalls at an orthogonal angle to the sidewalls, thereby forming an aperture below the plasma region. The aperture shield may comprise a plurality of shield sections, wherein at least one of the shield sections includes an upper shield plate, a bottom shield plate and a spacer positioned between the upper shield plate and the bottom shield plate. The upper shield plate may include perforations. Alternatively, the upper shield plate may include an electron filter, the electron filter may comprise a filter bar and a magnet array positioned within the upper shield plate. Also, the aperture shield may include two transverse aperture shields and two transport aperture shields, wherein the transport aperture shields include perforations. The sidewalls may comprise two transverse chamber walls along a transverse axis and two transport chamber walls along a transport axis, and the aperture shield may include two transverse aperture shields, each attached to one transverse chamber wall, and two transport aperture shields, each attached to one transport chamber wall.

The plasma chamber may further comprise an anode positioned inside the vacuum enclosure and incorporating an electron filter having exposed surface facing the plasma region and a hidden surface facing away from the plasma region, the electron filter generating a mirroring effect to deflect electrons onto the hidden surface. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

The disclosed embodiments provide a deposition system comprising: a vacuum enclosure having sidewalls, floor and ceiling; two sputtering targets positioned inside the vacuum enclosure and defining a plasma area therebetween, each of the sputtering targets having a front surface coated with sputtering material and a back surface, the front surface facing the plasma area; two magnetrons, each positioned behind the back surface of a corresponding one of the two targets; a gas injector mounted onto the ceiling and positioned centrally between the two targets; substrate transport tracks supporting substrate carriers below the plasma area; and an aperture shield attached to the sidewalls above the transport tracks and defining an aperture between the plasma area and the substrate carrier. The aperture shield may include an upper shield plate and a lower shields plate, wherein the upper shield plate is perforated or alternatively the upper shield plate may incorporate an electron filter. In either configuration, the aperture shield may be grounded and serve as an anode.

In embodiments the deposition system further comprises two peripheral anodes, each mounted onto the sidewall and positioned above the aperture shield and next to a corresponding one of the two targets, each of the peripheral anode comprising an anode block having a cavity, a magnet positioned within the cavity and generating magnetic field lines, and a cantilevered filter bar intercepting at least partially the magnetic field lines. and a central anode mounted onto the ceiling and positioned centrally between the two targets, the central anode having an anode block and a magnet positioned within the anode block; wherein the two targets, the two magnetrons, and the anode confine plasma within the plasma area to have a slope of log(I) vs. log(V) greater than at least 3 or greater than 4.

Also disclosed is a plasma chamber comprising a vacuum enclosure housing a target having a front surface facing a plasma region within the vacuum enclosure and a rear surface facing away from the plasma region, the front surface being coated with sputtering material; a magnetron positioned behind the rear surface igniting the plasma and confining the plasma to the plasma region; an anode position inside the vacuum enclosure and incorporating an electron filter having exposed surface facing the plasma region and a hidden surface facing away from the plasma region, the electron filter generating a mirroring effect to deflect electrons onto the hidden surface; and an anode aperture shield positioned to limit field of view to the substrates from the plasma and/or limit the deposition angle of particles reaching the substrates. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

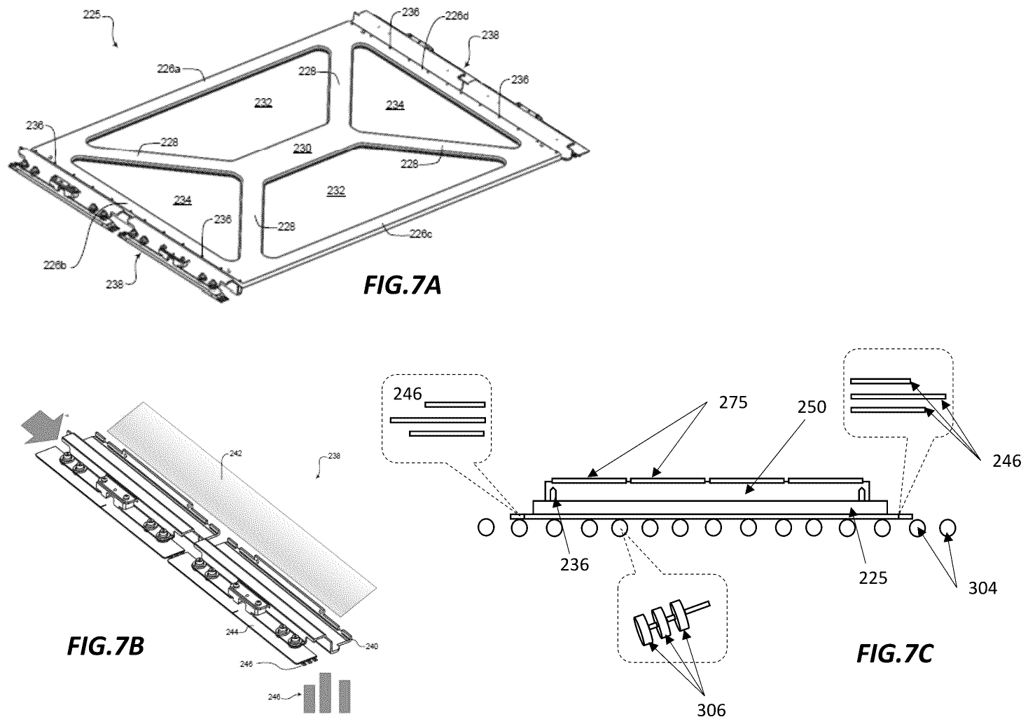

FIG. 6 illustrates in exploded view the overall construction of an embodiment of a substrate carrier 200. The substrate carrier includes three main parts: a carrier base 225, a carrier tray 250, and one or more substrate pedestals 275. The three main parts are assembled as illustrated to form the substrate carrier. Carrier base 225 is the lowermost part of the substrate carrier that supports the other two main parts and also provides an interface by which the substrate carrier can be coupled to a transport system such as the rail and wheels system shown in FIG. 2. Details of an embodiment of carrier base 225 are discussed below in connection with FIGS. 7A-7C.

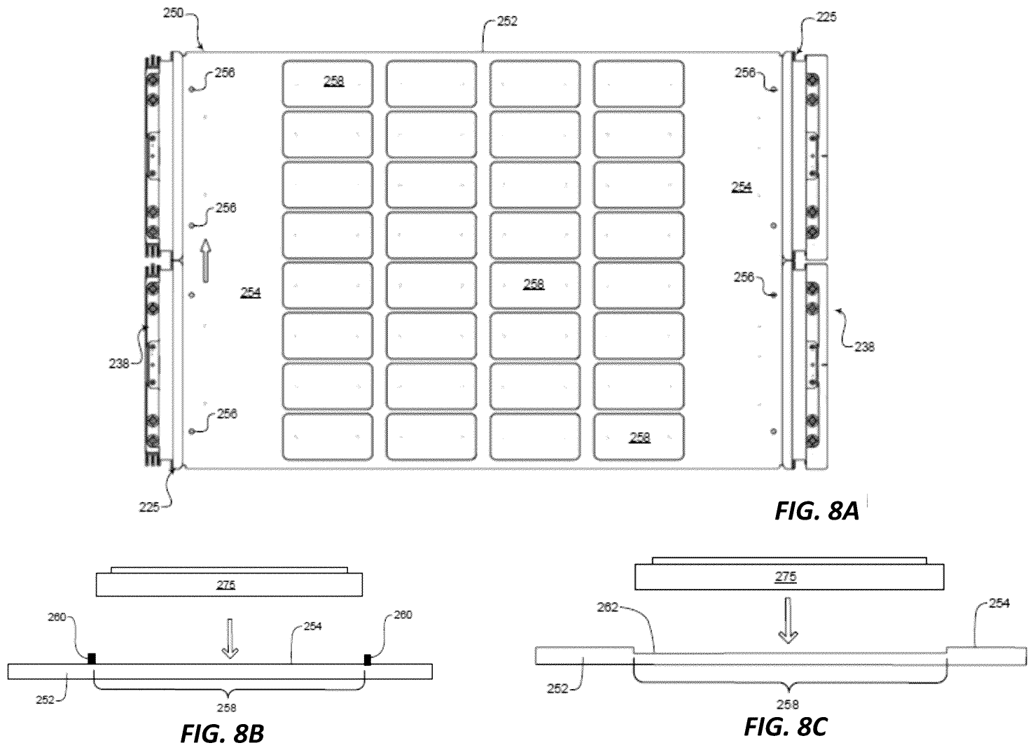

Carrier tray 250 is a middle part of the substrate carrier that provides an interface between the carrier base and the substrate pedestals and also supports the substrate pedestals (here shown with arrangement supporting six pedestals as but one example). Carrier tray 250 is placed on carrier base 225, using alignment features such as pins and holes, to ensure that the carrier tray is securely engaged with the carrier base and to ensure that the tray's alignment with the carrier base is accurate and repeatable. Details of an embodiment of carrier tray 250 are discussed below in connection with FIGS. 8A-8C.

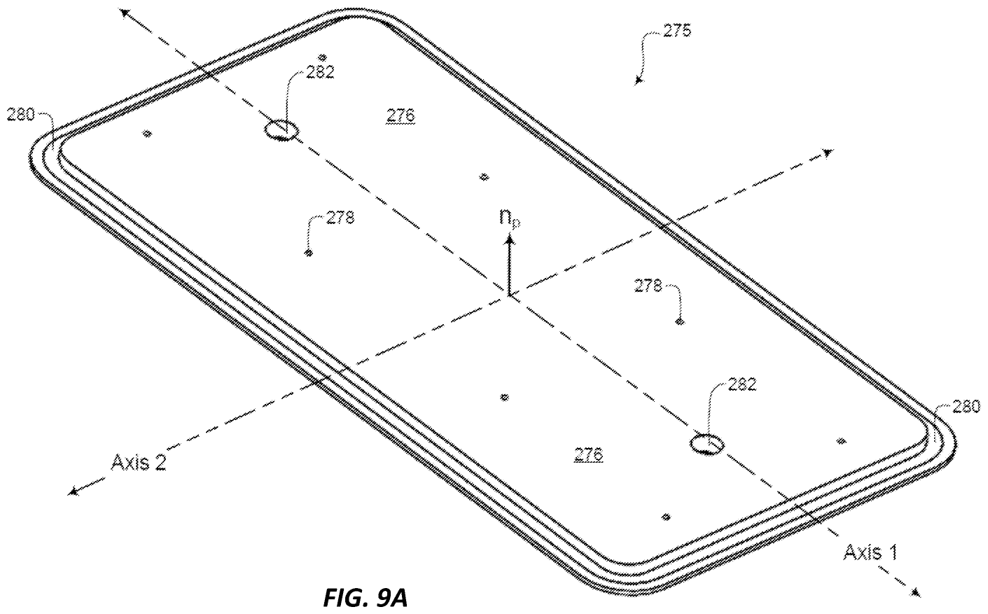

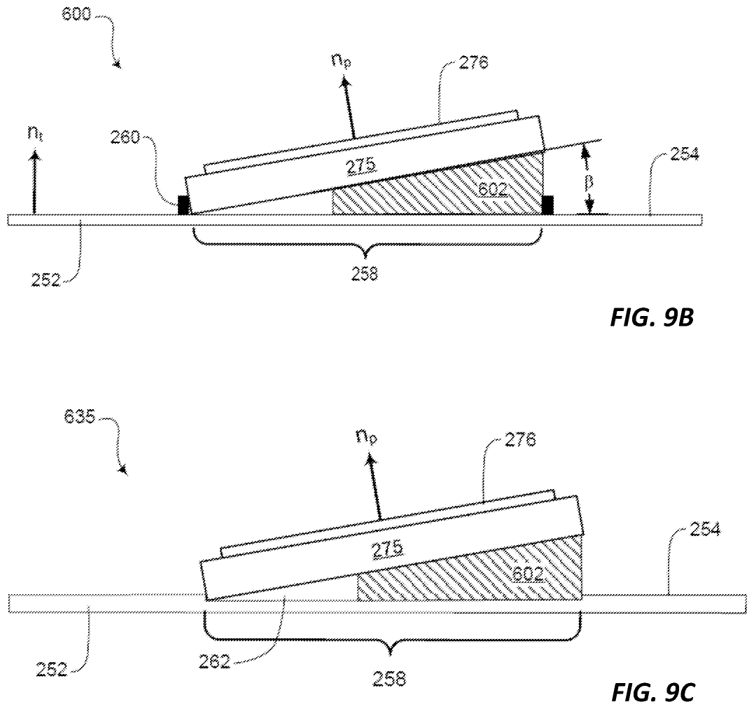

One or more substrate pedestals 275 are placed on carrier tray 250 to complete the substrate carrier. The illustrated embodiment shows only a single substrate pedestal being assembled onto carrier tray 250, but other embodiments can have multiple pedestals per carrier tray. Details of an embodiment of carrier pedestal 275 are discussed below in connection with FIG. 9A-9C.

FIGS. 7A-7C illustrate details of an embodiment of a carrier base 225. FIG. 7A illustrates the carrier base, while FIG. 7B the details of an embodiment of a transport interface by which the carrier base can be coupled to a transport system such as the rail-based transport system illustrated in FIG. 7C.

Carrier base 225 is quadrilateral in shape (here rectangular), although other embodiments need not be quadrilateral. The carrier base includes a thick rigid web body with edge supports 226a-226d, each positioned along one edge of the quadrilateral. The thickness of the rigid web body will depend on the material properties of the material used, the configuration of supports, and the expected loads. Generally, the thickness can be set so that the rigid web body can support the carrier tray, substrate pedestals, adjusters, and substrates with little or no deformation, so that the position and orientation of the substrates is not substantially affected by deformation of the carrier base. In one embodiment, for instance, the thickness of the rigid web body is greater than the thickness of the carrier tray, but in other embodiments the rigid web body can have the same or less thickness than the carrier tray, depending on the configuration and material of the rigid web body. A central support 230 is connected to edge supports 226 by diagonal supports 228. The illustrated embodiment has four diagonal supports 228 that connect central support 230 to the corners where each pair of edge supports 226 meet. This arrangement results in four voids or open areas—two trapezoidal voids 232 and two triangular voids 234—that reduce weight while also providing for support of carrier trays 250 and pedestals 275 without sagging or warping at process temperatures. Other embodiment of carrier base 225 can configure the carrier base differently than shown-for instance, with other configurations of supports 226, 228, and 230, or with different numbers of supports, different support shapes and dimensions, and different connections between supports. Transport interfaces 238 are positioned on opposite edges 226b and 226d in the illustrated embodiment, but can be positioned differently in other embodiments or when used with other types of transport system.

Carrier base 225 also includes alignment pins 236 for accurate and repeatable positioning, and rapid loading and unloading, of other substrate carrier components such as carrier tray 250. Generally, other components that will be placed on carrier base 225 will have corresponding alignment holes to receive and engage alignment pins 236. In the illustrated embodiment alignment pins 236 are positioned on opposite edges 226b and 226d of the carrier base, but in other embodiments the alignment pins can be positioned differently and distributed differently than shown. In other embodiments, carrier base can include alignment holes instead of alignment pins, in which case the other components can include alignment pins instead of alignment holes. In still other embodiments, other alignments features can be used, such as corner stops that engage corners of the carrier tray or edge stops that engage edges of the tray.

FIG. 7B illustrates details of an embodiment of transport interface 238, by which carrier tray 225 is coupled to a transport system. Transport interfaces 238 couple the carrier base to a rail transport system through carrier feet 244 and include a drive-side guide 240 that overlaps chamber guide flange 242 to guide the substrate carrier along a transport direction. Transport interfaces 238 also include transport feet 244 with magnetic toes 246, shown in the expanded view. In one embodiment, magnetic toes 246 are made of magnetic material and ride on wheels positioned within the chamber. The magnetic toes 246 have different toe lengths to increase the coefficient friction and come off magnetic wheels at different times in response to applied force as the carrier moves from one section to the other. This makes the transition from one section to another smoother, since the toes move from one wheel to the next in sequence, rather than all together at the same time.

FIG. 7C illustrates an embodiment of a substrate carrier such as carrier 200 used with a transport system. As described above, substrate carrier 200 includes three main parts: carrier base 225, carrier tray 250 and one or more substrate pedestals 275. The substrate carrier uses a transport interface such as interface 238, described above, to couple to a transport system 302. Transport interface 238 engages with multiple magnetic wheel assemblies 304 of the transport system, and each magnetic wheel assembly includes three wheels 306. Each carrier foot 244 includes three magnetic toes 246, each of which is a magnetic bar that rides on one of the three wheels 306. The three magnetic toes 246 have different lengths; in the illustrated embodiment the central toe is the longest and one of the outer toes the shortest, but in other embodiments the toes could be ordered differently than shown. The three toes increase the coefficient friction and come off magnetic wheel at different times in response to applied force as the carrier moves from one section of transport system 302 to another.

FIGS. 8A-8C illustrate embodiments of a carrier tray 250. FIG. 8A shows carrier tray 250 positioned on carrier base 225 and illustrates its basic construction. FIGS. 8B-8C illustrate embodiments of pedestal positions on the carrier tray.

Carrier tray 250 includes a thin tray 252 with a substantially flat deposition surface 254 that can provide a uniform sputter surface for deposition. In some embodiments, deposition surface 254 can include a rough surface to minimize coating delamination, including arc spray surface coating. In an embodiment where carrier base 225 includes alignment pins 236, thin tray 252 can include alignment holes 256 that engage the alignment pins to accurately and repeatably align the carrier tray on the carrier base. The illustrated embodiment has eight alignment holes 256 positioned along opposite edges of thin tray 252, with four alignment holes along each edge. Other embodiment can use a different number of alignment holes and can position and distribute them differently than shown. And in embodiments where carrier base 225 uses alignment holes instead of alignment pins 236, carrier tray 250 can correspondingly use alignment pins instead of alignment holes 256.

Carrier tray 250 also includes pedestal positions 258. The pedestal positions are an N×M set of positions, wherein N≥1 and M≥1. In an embodiment where M=N=1 there is a single pedestal position, but embodiments where M>1, N>1, or both, will have multiple pedestal positions. The illustrated embodiment has an 8×4 set of positions 258 arranged in a regular array, but other embodiments can of course have different numbers of positions (see, e.g., FIG. 6). In other embodiments positions 258 also need not form a regular array; they can form an irregular array, or no array at all. In one embodiment of carrier tray 250 all pedestal positions are the same—same size, same shape, same delineation—but in other embodiments all pedestal positions need not be the same.

FIGS. 8B-8C illustrate embodiments of pedestal positions 258. Each pedestal position 258 is sized and shaped to receive a corresponding pedestal 275, but the pedestal positions can be delineated differently in different embodiments. In the embodiment of FIG. 4B, for instance, pedestal position 258 can be bounded by stops 260 positioned around some or all of the position's perimeter. In the embodiment of FIG. 4C, a pedestal position 258 can be bounded by the edges of a surface depression 262 formed in thin tray 252. In other embodiments the pedestal positions can be formed differently; for instance, they can simply be marked on deposition surface 254. As further discussed below in connection with FIGS. 9B-9C, one or more pedestal positions 258 can include an adjuster by which the height, angular orientation, or both, of the pedestal's working surface can be adjusted. Adjusters positioned in the pedestal positions provide a mechanism to adjust the target-to-substrate distance or tilt of each substrate normal away from directly perpendicular to the substrate based on the height of the pedestal mounts.

FIG. 9A illustrates an embodiment of a carrier pedestal 275. Pedestal 275 can include a smooth and substantially flat working surface 276 to receive a substrate placed on the pedestal. Vent holes 278 prevent trapped gas from affecting part alignment upon vacuum system entry. Trench 280 is positioned to just cover the edge of the substrate and prevent edge or back-side deposition without shadowing the front-side deposition. Pedestal 275 can be made of a material with high thermal conductivity, such as aluminum, for temperature control during deposition.

Pedestal 275 has two orthogonal axes, Axis 1 and Axis 2, and the angular orientation of working surface 276 can be adjusted by rotating the pedestal about either or both axes. Put differently, working surface 276 has a normal vector np whose direction can be changed by rotating the pedestal about Axis 1, Axis 2, or both Axis 1 and Axis 2. When a substrate is mounted or held on working surface 276, changing the orientation of the working surface results in a corresponding change of orientation of the substrate. Rotation and translation of pedestal 275 can be accomplished with an adjuster in a pedestal position in which pedestal 275 is put. Adjusters can be any device, mechanism, or object that enables rotation and translation of the pedestal relative to the tray. Some embodiments of adjusters can use simple or complex mechanisms that can be set to any position or angle, while other embodiments can be simple objects such as blocks or shims. Some embodiments of adjusters are shown in FIGS. 9B-9C.

The illustrated embodiment of carrier pedestal 275, with substantially flat working surface 276, is appropriate for mounting a three-dimensional substrate with a mostly flat surface and curves near the edges. But in other embodiments working surface 276 need not be flat; mounts for a wide variety of substrates of different shapes and sizes, having flat surfaces or complex three-dimensional shapes, can be constructed. Whether working surface 276 is flat or not, its angular orientation can be adjusted as described above using the adjuster in the corresponding pedestal position.

FIGS. 9B-9C illustrate embodiments of adjusters in a pedestal position. The adjusters that can be used to adjust the angular orientation and position of the pedestal and its working surface relative to the carrier tray through rotation, translation, or both, of the pedestal relative to the carrier tray. By adjusting the position and orientation of the working surface, the substrate normal axis can be tilted to match the local average lateral angle of incidence and optimize coverage uniformity. The substrate surface plane can also be raised or lowered to adjust sputter source-to-substrate distance to tune both deposition and film stress. When used in a deposition chamber such as the one shown in FIGS. 1D, 1E, and 2, adjustment of the working surface's position and angular orientation relative to the carrier tray results in a corresponding adjustment of the working surface's position and angular orientation relative to the sputtering source.

FIG. 9B illustrates an embodiment of an adjuster 600 positioned between pedestal position 258 and its corresponding pedestal 275. Adjuster 600 uses a wedge shim 602 with a pedestal position such as the one of FIG. 8B, where the pedestal position is delimited by stops 260. Wedge shim 602 with wedge angle β is positioned in pedestal position 258 abutting a stop 260, and pedestal 275 is then lowered onto the wedge shim. Stops 260 prevent the pedestal and wedge shim from sliding laterally. The wedge shim changes the orientation of working surface 276, with the shim's angle β tilting the working surface's normal vector nₚ by β degrees relative to the normal vector nₜ of deposition surface 254. In different embodiments, wedge angle β can be any value between 0 degrees and 75 degrees. Also, in some embodiments wedge shim 602 can be a compound wedge that simultaneously tilts normal vector about multiple axes, for instance about Axis 1 and Axis 2 shown in FIG. 9A. Wedge shim 602 can include holes therein (not shown in the figure) that fluidly couple with pedestal vent holes 278 (see FIG. 9A) to allow the vent holes to perform their venting function.

FIG. 9C illustrates another embodiment of an adjuster 635. Adjuster 635 is in most respects similar to adjuster 600, but can be used in embodiments where pedestal position 258 delimited by surface depression 262 formed in tray 252. In this embodiment, then, wedge shim 602 can be held in place by the edges of surface depression 262, so that the edges prevent the shim and the substrate pedestal from moving laterally.

With the above disclosure a sputtering chamber is provide, comprising: a vacuum chamber; a cylindrical target within the vacuum chamber and having sputtering material on exterior surface thereof; a magnet arrangement provided inside the cylindrical target, the magnet arrangement comprising a first set comprising a plurality of magnets arranged on a single straight row, each magnet of the first set having a first pole facing interior wall of the cylindrical target and a second pole facing away from the interior wall, a second set comprising a plurality of magnets arranged in a obround shape around the first set, each magnet of the second set having the first pole facing away from the interior wall of the cylindrical target and the second pole facing the interior wall; a keeper plate positioned between the first set of magnets and the second set of magnets, such that a straight line passing through an axis connecting the first pole and the second pole of a magnet from the second set intercepts the keeper plate prior to reaching the interior wall, while a straight line passing through an axis connecting the first pole and the second pole of a magnet from the first set reaches the interior wall without having to intercept the keeper plate; and a carrier tray having a deposition surface; an N×M set of pedestal positions on the deposition surface, wherein N≥1 and M≥1, wherein each pedestal position is adapted to receive a corresponding substrate pedestal, and wherein each pedestal has a working surface adapted to receive a substrate; and one or more adjusters, each positioned in a corresponding pedestal position, wherein each adjuster can adjust a distance between the deposition surface and the working surface, an angular orientation of the working surface relative to the deposition surface, or both.

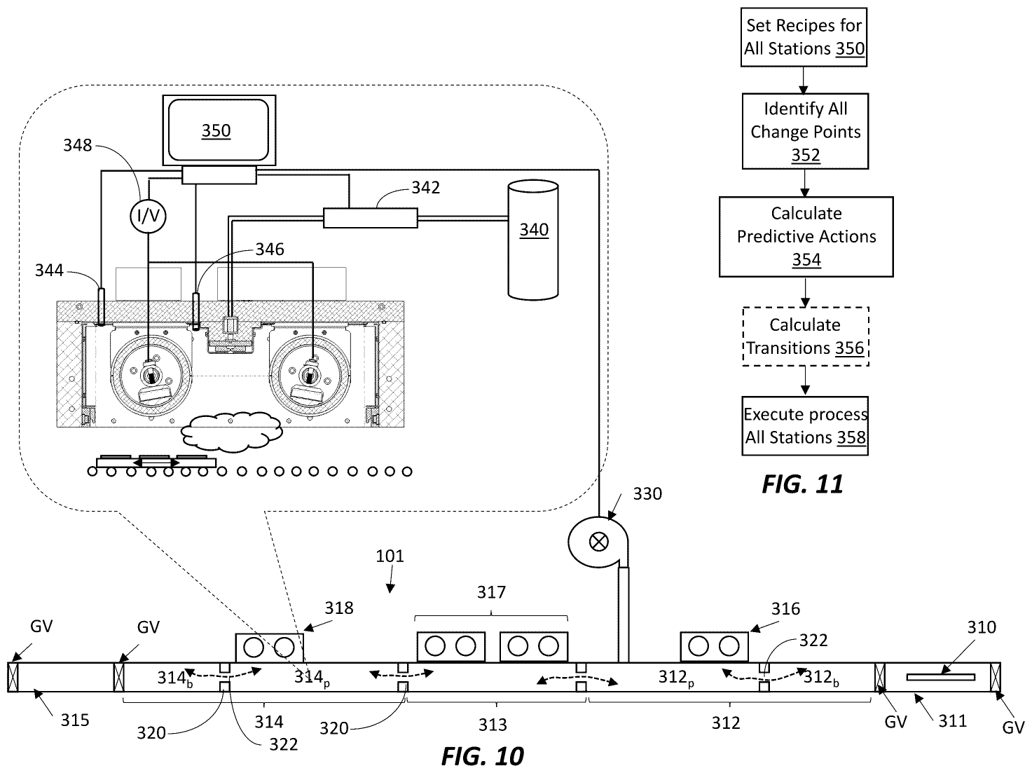

The description will now proceed to explain the hybrid system architecture and process control. A hybrid deposition system compatible with some embodiments is illustrated in FIG. 10. Hybrid deposition system 101 includes an entrance load lock station 311, into which a carrier 310 holding multiple substrates to be coated may be loaded from atmosphere and pumped down to vacuum processing condition during a processing cycle period; a first thin film coating station 312 that deposits multiple thin film layers in a back-and-forth process during a processing cycle period; a second thick film single-pass processing station 313 that continuously deposits film as multiple head-to-toe carriers slowly pass through the station, progressing by one carrier length during a processing cycle period; a third thin film coating station 314 that deposits multiple thin film layers in a back-and-forth process during a processing cycle period; and an exit load lock station 315 that receives a carrier after deposition is completed, and completes vent, unload and pump-down during a processing cycle period.

In the system, the load locks are isolated by gate valves GV; however, the deposition stations are separated by partitions 320, each having a transport opening 322 for the carriers without gate valves, i.e., without the need to close the transport openings. Therefore, during processing gasses can flow between the deposition stations through the transport openings 322. Note also that cycling stations 312 and 314, which perform back-and-forth process during a processing cycle period, include a buffer section 312b and 314b in which no process is being performed, and a processes station 312p and 314p, in which processing takes place. The buffer section is separated from the processing section with a wall having a transport opening. A gate valve to isolate the stations for service is optionally available, but is not employed for production operation. In the illustrated embodiment, each of the cycling stations 312 and 314 includes a sputtering source 316 and 318 respectively, according to any of the embodiments disclosed herein, e.g., a dual-target arrangement shown in FIG. 2. The single-pass processing station 313 includes two sputtering sources 317 according to any of the embodiments disclosed herein, e.g., two dual-target arrangement shown in FIG. 2.

The system of FIG. 10 is configured to process the substrates over a prescribed cycle period, after completion of which all substrate carriers will have moved to the same position the prior carrier was in at the end of the previous cycle. This may be achieved by having all of the carriers in the system move in unison to the next cycle start position at the beginning or end of a cycle, but that is not required as long as each carrier within the system proceeds through the chamber in a series of repeated equal duration cycles wherein no carrier cycle intersects in space and time. As an example, the system can be configured for deposition of six different layers of SiOxNy on each substrate, with, say, 100 second process cycle. In such an example, cycling station 311 is programmed to perform the process according to the timing chart as follows: at time T=5, power turned on and gas flow set for layer 1. For example, power is set to 30 kW and gas flow to Ar: 100 sccm, N₂:10 sccm and O₂:150 sccm, to form a layer having refractive index of n=1.5. At time T=10 the carrier is moved from the buffer section 312b to the processing section 312p, and the carrier is moved forth and back to deposit the first layer until time T=50. At that time the power and gas flow are modified to the conditions needed to form the second layer having a different refractive index, e.g., n=1.7. The conditions may be, e.g., power is reduced to 10 kW and gas flow adjusted to Ar:90 sccm, N₂:5 sccm and O₂:50 sccm. At T=55 forth and back transport of the carrier resumes. Notably, between times T=50 and T=55 the carrier may be placed in the buffer section 312b. At T=90 processing stops and the carrier is moved to single-pass station 313.

At single-pass station 313 a single layer, layer 3, is formed in a single slow-moving pass of the carrier. That is, the transport speed of the carriers in stations 312 and 314 is higher than the transport speed in station 313. Setting for station 313 may be, e.g., power 40 kW and gas flow Ar:70 sccm, N₂:200 sccm and O₂:10 sccm, for refractive index n=2.0. The set up is for both sputtering sources for the entire cycle period and doesn't change. The carrier continuously moves through station 313 and then enters station 314.

Three different layers, layers 4, 5 and 6, are formed in station 314 as follows. At time T=5, power turned on and gas flow set for layer 1. For example, power is set to 30 kW and gas flow to Ar: 100 sccm, N₂: 15 sccm and O₂: 150 sccm, to form a layer having refractive index of n=1.5. At time T=10 the carrier is moved from the buffer section 312b to the processing section 312p, and the carrier is moved forth and back to deposit the fourth layer until time T=30. At that time the power and gas flow are modified to the conditions needed to form the fifth layer having a different refractive index, e.g., n=2.0. The conditions may be, e.g., power is reduced to 20 kW and gas flow adjusted to Ar: 70 sccm, N₂: 100 sccm and O₂:5 sccm. At T=35 forth and back transport of the carrier resumes until time T=65. At T=65 the power is set to 30 kW and gas flow to Ar: 100 sccm, N₂: 15 sccm and O₂:150 sccm, to form a sixth layer having refractive index of n=1.5.

Throughout the multiple layer process cycle such as that just described, continually varying amounts of process gas are flowing back and forth between stations 311, 313, and 314, through the transport slots as indicated by the dotted arrows. During the entire 100 second cycle there is always some slow variation in the gas flow that is able to escape from each station as the various ongoing carrier motions block line-of-sight to the slots and pumps, affecting conduction of the vacuum system. More abrupt changes affecting gas exchange between stations correspond to layer changes. For example, at T=5 seconds, both station 312 and station 314 rapidly change gas flow exiting into station 313 as power is increased to 30 kW. At T=30 seconds station 314 rapidly increases oxygen flow and decreases both nitrogen argon while changing power. At T=50 seconds station 312 rapidly decreases oxygen, nitrogen and argon gas flows while also reducing power. At T=65 seconds station 314 rapidly increases oxygen and argon gas flows, reduces nitrogen and increases power. At T=90 seconds station 312 and/or station 314 may power off or reduce power, briefly bursting reactive gases as reactive consumption ceases or reduces. Complex bursts of rising and lowering gas flows traversing the slots connected to the steady state station 313 will occur at each transition event. Reactive compensation cannot respond fast enough to compensate for such complex and rapid system changes. In order to determine the correct compensation for such events, it is necessary to analyze and predetermine the nature of the change and apply a predictive correction to compensate for the change.

In some embodiments, reactive process controls comprise monitoring a plasma readback such as the voltage during stable deposition in a constant power mode; and setting a response function to automatically adjust the flow of reactive gas in response to any measured change in the voltage. For example, in the art of SiOxNy reactive deposition from a Si cathode target, increasing reactant lowers cathode voltage so that a more stable process is achieved by increasing a reactive gas flow whenever voltage increases and lowering it when voltage decreases. Other monitored variables including average voltage of multiple cathodes, pressure and optical measurements from a PEM (plasma emission monitoring) sensor as well as alternate control parameters such as Oxygen flow, nitrogen flow or Ar flow are also available for machine learning as well as manufacturing purposes. The PEM sensor is a photosensor that acquires real-time plasma emissions spectra to control and manage plasma-based processes.

The callout in FIG. 10 illustrates controller 350, which may be in the form of especially programmed general purpose computer or dedicated computing platform, coupled to various elements of the processing system to perform the control according to disclosed embodiments. Gasses for the processing are provided from gas source 340, which is coupled to a gas stick 342 on gas panel, which include MFC (mass flow controller) controlling the gas flow into the stations according to signals from controller 350. Power to the cathodes is provided from power source 348, the voltage and current of it being measured and monitored by controller 350. The pressure inside the stations can be measured by pressure sensor 344 and reported to the controller 350. Also, optical emission of the plasma within each station can be monitored by PEM sensor 346 and reported to the controller 350.

While running different processes in the connected stations of the system of FIG. 10, there will be changes to process variables such as pressure, voltage, and PEM sensors, which can be studied beforehand and predicted. For example, stable single station processes for Layer 1, Layer 3 and Layer 4 may be defined. To get the same film deposition condition and film properties of each layer run simultaneously may require significant changes to process settings that reactive process control cannot immediately and optimally correct for because it only reacts. However, predictive adjustment functions can be sent directly to profibus mass flow controllers (MFCs) 342 at the correct time to keep the process variables steady as the interactive environment is changed. The predictable changes will be mostly invisible to the reactive controls because they will be counteracted immediately by the predictive process control.

In disclosed embodiments, it may be insufficient to simply observe the steady state before and after a process change to define the required adjustment. The detailed predictive adjustment function depends on the specific timing of changes to the critical process parameters in order to make the fast, stable change from one process to another. Thus, in some embodiments a learning algorithm is employed to determine the optimal predictive correction function. An initial correction function can be defined based on the steady state process adjustment and the layer transition recipe, and then a final correction function is selected by iteratively running the layer transition recipe and corrections until a smooth transition that does not significantly affect the reactive process controls is achieved.

As a simple example, referring to the above example process, during the transition from layer 1 to layer 2 in station 312 at T=50, the flow of Ar, N2 and O2, is reduced. In this example an initial assumption is that 10% of the gas from station 312 flows into station 313 through the “leaky” open transfer port. However, since at T=50 the flow into station 312 is reduced, the “leaky” flow into station 313 would also be reduced. Therefore, the predictive correction would, at T=50, adjust the station 313 recipe by increasing each gas flow by 10% of the amount of reduction in the corresponding flow in station 312. For example, if at T=50 Ar is adjusted from 100 sccm to 90 sccm in station 312, i.e., a reduction of 10 sccm, then the Ar flow into station 314 (previously 70 sccm) should be increased by 10% of 10 sccm, i.e., by 3 sccm to 73 sccm.

Incidentally, the initial assumption of 10% gas leak could be obtained, for example, by an experimental setup of flowing gas only in station 312 and measuring the pressure in station 312 and station 313 with and without a slot valve opened between the two stations. The pressure changes would show how much gas is flowing from station 312 to station 313. For example, a gas leakage correction factor can be stored in the controller 350, and the controller 350 can modify the recipe for the second station using the gas leakage correction factor. More efficiently, the iterative training could be applied to all or any of the flows in station 312 (eg. Ar only) without power, to determine Ar flow changes in station 313 needed to maintain constant pressure in station 313.

If, with this adjustment, the process voltage drops in station 313 by 20 volts, showing that there is too much reactive gas with the adjustment, the next iteration would reduce the reactive gas flows into station 313 from the initial correction, until the voltage in station 313 remain constant. That is, if the initial adjustment provided too high voltage in station 313, the reactive gas flows therein would be reduced until the process voltage remained constant across the layer transition occurring in station 312. The cycle of learning repeats until the voltage stays within a specified range.

An oscillating voltage response in station 313 with no overall voltage change, owing to the layer transition in station 312 can similarly be corrected by adjustment of the timing and change rate of the gas adjustments by a similar iterative process to minimize oscillation amplitude. Thus, the programmed changes in one station are used to proactively adjust the process in a neighboring station by predicting the effect of the change in one station on the process in the neighboring station. By using more sensors such as pressure and PEM optical detection of the reactive gas mix at different locations within a station, the process conditions can be adjusted in more dimensions and with higher accuracy and predictability. For example, the plasma emission monitor (PEM) sensor can be monitored in station 313 and the gas flow rate adjusted reiteratively until the PEM sensor remains constant during the change in the gas flow rate in station 312. Similarly, the pressure can be monitored in station 313 and the gas flow rate adjusted reiteratively until the pressure remains constant during the change in the gas flow rate in station 312.

The above predictive process control helps address the problem that the different processes are performed in different stations affect neighboring station because of gas flow through the open transfer port. Therefore, for example, a different correction factor is needed for each gas flow in station 313 for each moment of the multiple layer process in station 312. Consequently, the instantaneous optimal flow corrections in station 313 is determined during the entire duration of the multiple layer process cycle in station 312 by iterative process training. Furthermore, if there's also a changing process in station 313, it is extremely difficult to separate out those changes from the station 312 effects. Similarly, if there is a third station 314 running a multiple layer process, it is necessary to develop a trained correction for both simultaneous inputs changing layers at multiple different times and constantly as a function of carrier position changing gas conductance. Thus, the initial predictive control with iterative training helps account for various effects of multiple process changes in real time.

Thus, another example embodiment of the iterative training process operates as follows. The system cycle time is set to a 100 second repetitive process in station 312, station 313, and station 314, such that, in subsequent cycles a carrier will move from a starting position entering station 312 to a starting position entering station 313, to a starting position entering station 314. The variable argon flows and timed carrier motions in station 312 and station 314 are prescribed in a 100 second recipe for each station. A 100 second recipe for the in-line carrier motion in station 313 is also programmed, along with a starting Ar flow in station 313. The recipes are run simultaneously, and pressure in station 313 throughout the 100 second cycle is recorded. Considering flow delays from MFCs, an algorithm raising flows in station 313 slightly in advance of measured pressure drops, and lowering flows in station 313 slightly in advance of measured pressure increases is employed. The three recipes are simultaneously repeated, and the pressure in station 313 throughout the 100 second cycle is again measured and flow corrections applied. By this iterative process, a precise set of flow adjustments in station 313 can be determined, that maintains a stable constant Ar pressure in station 313, accounting for all carrier motions and Ar flow changes that occur in all three stations during the specified full system process. More generally, this basic technique can be applied to provide precise process control for a specified process including any number of carriers and stations. It can also be employed more generally to optimize processes with power on, with reactive gases, and using different feedback sensors to probe and maintain other desired process or plasma properties that may require defining a predictive correction prior to or during process operation.

By this disclosure, a method is provided for implementing in a plasma processing system having a first station and a second station and a partition between the first station and the second station, the partition having a transport opening that is permanently open during processing, a method comprising: setting a first process recipes for the first station comprising specification for at least one of, a gas flow rate, a carrier transport speed and position, and a cathode power during a repeatable timed process; setting a second process recipe for the second station comprising specification for at least one of, a gas flow rate, a carrier transport speed and position, and a cathode power during a repeatable timed process of equal duration to the repeatable timed process of said first station; setting a target of output value for a process parameter measured in said second station; measuring said output value for the process parameter measured in said second station; and iteratively correcting the process parameter until said output value minus said target output value is less than a selected value for every measurement obtained during said repeatable timed process.

Another aspect of some embodiments is a method and apparatus to achieve rapid stable transitions of process settings from one layer to the next so as to maximize throughput of multiple layers in batch stations. The process conditions may differ in gas flow, power, and target voltage. These embodiments can be given two layers process conditions, and automatically determine a rapid transition recipe between them. That is, instead of switching directly from a first process recipe setting to the second process recipe settings, the system employs an algorithm to determine an initial transition recipe between the two desired process conditions. The algorithm based on prior experience selects step order and change rates of power and gas flows to achieve the transition rapidly without a transition specification failure. Transition specifications failures include poisoning the targets, arcing, loss of plasma, overvoltage, too large target voltage fluctuations at the end of the transition and too much time. Failure parameters such as transition time can be variable so that the algorithm provides more or less complete optimization. Some embodiments automatically test the transition recipe. If it does not stay within the defined specifications, adjustments are made automatically. Testing and adjustment iterations proceed until transition specifications are met. In some embodiments the algorithm for determination of the initial recipe itself employs continuous machine learning based upon the difference between initial and final transition recipes for each new transition it optimizes.

In a very simple example application of one of the embodiments, the first process condition is 40 kW for depositing a layer of SiO2, and the second process is 40 kW for deposition of Si3N4 layer. At the change point, rather than shutting off O2 and turning on N2 flow, the transition recipe would controllably reduce O2 flow and gradually introduce N2 flow, both at a rate calculated to provide fast recipe change without causing any process failure. The embodiment would test the transition recipe on the system automatically by iteration until the best transition is achieved. If the transition did not meet the specifications, the transition recipe flow rate changes would be adjusted depending on the failure type, or the duration of the transition recipe would be increased. For example, a target poisoning failure could trigger a short delay between oxygen reduction and nitrogen increase while overvoltage might trigger a faster nitrogen increase and a slower oxygen reduction. Cycles of testing and adjustment would continue until the transition met the specifications.

Further embodiments of the predictive aspect of the process correction may be applied to the slow variations of process environment that occur within a deposition system during long-term operation. Slower feedback loops and cycles of learning may be employed for machine learning using data regarding film properties measured after deposition combined with the logged system readbacks, to provide predictive corrections that improve film properties and uniformity of films produced hours and days apart. Example applications include maintaining film refractive index by reducing oxygen flows as outgassed water or even factory humidity are found to be high; and maintaining full stoichiometric reactivity across a carrier by adjusting gas flow laterally across the cathode as target erosion profiles affect local sputter rates.

FIG. 11 is a flow chart illustrating a process according to an embodiment that may be executed by a programmed general-purpose computer, a specialty computing machine, an artificial intelligence machine, etc. As noted, an initial estimate for gas leak rate among the station may be derived empirically by flowing gasses into the stations without igniting plasma and measuring the leakage rates by, e.g., measuring changes in pressure in the stations. The controller 350 can be programmed to use the initial estimate and execute the processing in the system using predictive control as shown in the example of FIG. 11. In step 350 the recipes for all of the stations are programmed. For each of the stations, the recipes may include change points wherein the recipe indicates new settings, such as new gas flow rate, new cathode power, etc., in order to deposit a different layer. At step 352 all of the change points are identified and at 354 the initial estimates are used to calculate the predictive actions as explained in the examples provided above. The predictive actions are calculated for neighboring stations based on estimated or empirically derived gas flow leakage among the stations. Thus, for example, if at a change point the gas flow is increased in one chamber, the initial estimate can be used to determine a gas flow decrease in the neighboring station. In an optional step 356, transition recipes are developed for the change points, so that the controller first executes the transition recipe when it reaches a change point, rather than directly executing the process recipe of the change point. Alternatively, the controller executes calculates the transitions of step 356, and the predictive actions of step 354 are optional and may not be prepared and/or executed. At step 358 the process is executed according to the recipes for all stations, the predictive actions, and/or the transitions.

The disclosure turns now to the use of the above system with the various disclosed features to produce thin-films on substrates. As already noted, much of the utility of the system is in the sputtering of optical films for enhancing and protecting transparent substrates, such as electronics cover glass, e.g., touch screens. Such glasses require multiple films of various properties, depending on each film's function. The stack of these films enhances the optical properties of the glass, such as by providing anti-reflection function, and also enhance the physical properties of the glass, such as by increasing strength and/or providing anti-scratch function. Examples of the fabrication and properties of such films will be disclosed below.

In one embodiment, a low index fully reacted 2 micron SiOxNy film with refractive index of n=1.7 and nano-hardness of 20 GPa is formed in pass-by mode at a rate of about 65 nm*(mm/s)/(kw/m), that completes in about 3 minutes employing one meter long rotating cathodes operating at 40 kW. In this respect, the substrate carrier speed is expressed in millimeter per second (mm/s) and functions as the metric for the inverse of time (1/T)—the faster the carrier speed, the less time the substrate is exposed to the sputtering and the less thickness of film is deposited. The power applied to the cathode is expressed in kilowatt per meter (kW/m) as the power is divided by the cross-track length of the cathode. Thus, it is proportional to the number of atoms that will be deposited from one cathode location based on changing power. Consequently, the expression 65 nm*(mm/s)/(kw/m) is a normalized rate because, when the 65 nm*(mm/s)/(kw/m) is multiplied by the power density (kW/m) and multiplied by deposition time (1/mm/s), those normalizing units for power and time cancel the rate units, leaving only the (nm) thickness as a result of sputtering for a specified time at a specified power.

A positive clocking angle toward the chamber centerline is employed, sufficient that no low-density film is formed at any point between the cathode centerlines. Gas flows are reactively controlled to maintain a voltage on the higher voltage, unpoisoned, “metal mode” part of the voltage vs reactive gas curve to enable low pressure, high voltage, high adatom energy deposition. In this respect, poison mode refers to sputtering process wherein gas flow and process parameters are such that some of the gas species reacts and forms oxides on the surface of the target (e.g., N2 reacts with silicon target to form SiNx on the surface of the target), while metal mode refers to the conditions wherein substantially no oxides form on the active surface of the target during the sputtering process.

Using the disclosed system, a film of fully reacted, low visible-light absorption, high transmission, low index k below 0.001 at 400 nm wavelength can be achieved for the full range of indexes from n˜1.46 to n˜2.05, at pressures from about 0.5 mT to 10 mT and beyond. As pressure is reduced, SiNy can be formed with nanoindenter hardness of about 25 GPa. SiOx can be formed with hardness above 8 GPa and correspondingly high hardness layers can be achieved at all refractive indexes in between, including measured values above about 12 GPa at refractive index n=1.5, 14 GPa at n=1.6, 17 GPa at n=1.7, 20 GPa at n=1.8, 22 GPa at n=1.9, and 24 GPa at n=2.0. Factors enabling such high hardness and high deposition rates include: increased hardness and rate from the magbar plasma confinement, increased film density from clocking angle of the magbars, hardness and uniformity from filtering low energy deposition such as by an aperture anode and electron filters, maximized hardness and rate by simultaneous optimization of the clocking angle and aperture opening, and increased hardness from the high voltage metal mode deposition enabled at low sputter gas pressure.

In another embodiment, it is desirable to reduce the compressive stress of the film throughout its entirety or at selected depths within the film such as to reduce interface stress, improve film toughness and improve adhesion to a substrate or a subsequent layer. One powerful method is to remove or adjust the dimension of any aperture shields so as to enable deposition of a desired amount of low energy deposition comprising a desired portion of the depth of a deposited film. A single pass deposition past cathodes having a positive clocking angle toward the chamber centerline sufficient that no low-density film is formed at any point between the cathode centerlines can reduce film density at top and/or bottom sublayers of the film. That is, by increasing the clocking angle to generate high density film at the center between the two targets, and by allowing shallower angle species to reach the substrate at the edges of the chamber thereby forming a lower density film, as the substrate enters the chamber it is first coated by the lower density film, then as it moves towards the center of the chamber below the two targets a higher density film is formed, and as it moves away towards the exit, again a lower density film is formed. Consequently, by proper setting of the clocking angle, the anode aperture, and the substrate transport speed, the film may have lower density at the interfaces and higher density in the middle. The amount of lowered density and thickness of the sublayers can be adjusted by aperture design or variable pass-by transport speed. Compressive stresses can be reduced from upwards of 1 GPa to below 300 MPa or even 100 MPa while retaining reduced but still high hardness, by selection of higher pressure and regions of the chamber including lower energy deposition.

In other embodiments, the clocking angle of one or both cathodes may be reduced until a low-density stress-relief layer can be formed near the centerline of the deposition chamber, and thus over a selectable range within the depth of the layer. Such a film structure maximizes surface hardness and scratch resistance while simultaneously increasing toughness and resisting brittle fracture.

In yet other embodiments, multiple rapid passes through the deposition chamber while employing appropriate clocking angles and aperture designs described above can provide a synthetic multilayer structure comprising a multitude of different constructed density gradient patterns within the film layer. Correspondingly, many material property benefits of employing a multilayer composite film can be achieved in a single rapidly deposited film by this method. Film structures produced by such embodiments can often be directly observed by microscopy techniques such as scanning electron microscopy (SEM) and transmission electron microscopy (TEM).

In still other embodiments, even more profound multilayer structures may be formed by multiple passes through the system wherein the different cathodes of a cathode pair comprise different target materials. In yet other embodiments the power driven to each cathode may be different such that one has different rate, deposition voltage and deposition stoichiometry. The lower power cathode may for example be driven to operate in a low voltage “poisoned mode” with the target in a low conductivity state owing to a surface covered by a reacted oxynitride layer while the other target surface remains unreacted with the higher conductivity bare metal or semiconductor in a high voltage “metal mode”. Multiple pass films with such deposition conditions can provide multilayer structures with very strong periodic composition and density fluctuations for a wide variety of applications. Many of the enabled multilayer structures include very thin laminates that provide extremely stable averaged optical properties of the much longer wavelength visible light, high nano-hardness only marginally lower than a fully dense film, resistance to brittle fracture and significantly improved mechanical toughness owing to the mechanical spring like behavior of a multilayer.

In some embodiments it is further possible to alter optical properties outside of conventional ranges by controlling pressure and tuning deposited film energy as described. Refractive index of the films of the SiOxNy system have been reduced from n=1.46 down to about n=1.3 owing to film density reduction, while maintaining transparency and stable mechanical properties. Such novel film properties can have significant benefit in improved performance of optical films including anti reflective coatings.

Some embodiments combine the novel range of films that are enabled so as to provide completed multiple layer structures. For example, a protective hard optical overcoat stack may include thin layers optimized for adhesion and matching the optical index n and mechanical flexibility of the substrate; a thick hard layer with hardness and toughness optimized for the mechanical flexibility of the substrate; and multiple thin layers with n index values optimized to provide the most antireflective coating (ARC) layers consistent with maintaining mechanical requirements. A hard overcoat ARC structure for an already hardened glass substrate might prefer a film stack with an initial reduced stress adhesion layer followed by a series of fully dense high index layers with maximized hardness followed by an ARC design built with layers optimizing hardness at the low optical indexes required for high transmission. A hard overcoat ARC structure for a flexible polymeric substrate may in contrast require tougher, less brittle adhesion layers that also provide a refractive index to match a substrate value above or below that of glass. For a substrate index n=1.6 or 1.4, a high pressure, reduced deposition energy film deposition may be necessary to achieve the required properties. The optimal hard layer for such a flexible substrate may comprise a thick layer with significant hardness but with primary focus on low index, low stress, low density or a density gradient multilayer for maximum toughness and adhesion during flexion. The ARC design may focus on maximizing light transmission, and thus require the maximum index range compatible with moderately high hardness consistent with a non-brittle, flexible, tough protective overcoat.

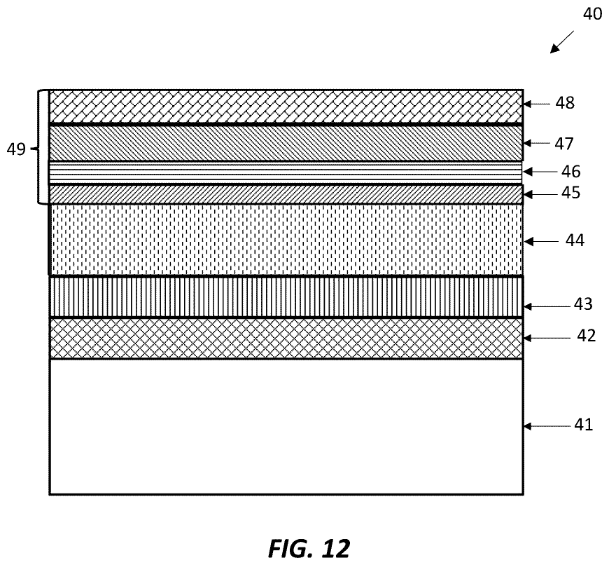

FIG. 12 shows a cross-section of an exemplary hard optical protective overcoat film stack 40 including novel film layers consistent with several embodiments described above deposited on a substrate 41. Substrate 41 is illustrated as a flat plate but may comprise any flat, curved or other three-dimensional shape that fits into the deposition chamber, including but not limited to screens for cell phones, smart watches, foldable devices, VR goggles, pads, laptops and automobile screens. Substrate 41 may include conventional or hardened glass, or a ceramic, plastic, polymeric, or other material. In some example embodiments, deposited layers are formed from a silicon cathode target and comprise SiOxNy films.

Adhesion layer 42 deposited onto substrate 41 is formed to have the same refractive index as substrate 41 so as to minimize frequency dependent reflectivity oscillations that increase in amplitude with increasing index mismatch. Deposition pressure and adatom energy for adhesion layer 42 may be selected or adjusted during deposition to reduce film stress and retain the refractive index match at the substrate interface as well as throughout the adhesion layer 42 thickness. Adhesion layer 42 is often less than 200 nm thick, but may be thicker, particularly in cases of softer flexible or plastic substrates where adhesion challenges may be extreme. In some embodiments an intermediate layer 43 is included between adhesion layer 42 and thick hard layer 44 so as to reduce interface stress between layers. Intermediate layer 43 generally includes a refractive index between that of adhesion layer 42 and thick hard layer 44, and may also include a stress relieving low density region. Intermediate layer 43 is generally less than 200 nm thick.

In several embodiments, thick hard layer 44 may comprise about two microns of material optimized for uniformity and high hardness at a specified index. One preferred embodiment comprises a high hardness of nearly 20 GPA while maintaining high toughness by achieving that hardness at a low refractive index of about n=1.7. Other embodiments may employ a 1-3 micron layer with refractive index about n=2.0, with lower density for stress reduction. Soft and flexible substrates may require a thinner and even lower index hard layer, such as 0.5-1.5 microns at refractive index n about 1.6.

Film stack 40 further comprises antireflective coating (ARC) layer stack 49 including sublayers 45, 46, 47, 48. There are many different specific thicknesses, indexes and number of sublayers that provide good anti-reflective properties as can be calculated by a variety of available computer models that apply the basic principles of reflection cancellation by quarter wave plates. Generally, it is required to provide ARC sublayers 45-48 with accurate index and thickness control with one or more having index n significantly higher than that of the hard layer 44 followed by at least one layer having index n much lower than that of the hard layer 44.

For example, a film stack 40 comprising: a substrate with n=1.46, a 100 nm adhesion layer 42 having matching index 1.46, a 100 nm intermediate layer 43 having index 1.60, and a 2 micron hard layer 44 having index 1.70; first ARC sublayer 45 may comprise n=1.90, significantly higher than that of the hard layer 44, second ARC sublayer 46 may comprise n=1.80, third ARC sublayer 47 may comprise n=1.90, and fourth ARC sublayer 48 may comprise n=1.5—lower than the index of the substrate and much lower than that of the hard layer 44. Exact thicknesses for optimum optical performance depend on the detailed frequency dependent optical properties of all layers including the substrate, but ARC sublayers generally range from about 10-150 nm thick for most practical designs. First ARC sublayer 45 requires a uniform process and index, but may benefit from stress relief at the interface with hard layer 44 having a refractive index and material composition mismatch. Second ARC sublayer 46 and third ARC sublayer 47 have similar index and thus relatively small interface mismatch so optimization of the entire structure for the given application may be paramount. In some embodiments the layer design focus could be for maximum hardness and uniformity while in others it might be to minimize brittleness or stress in the film stack. In yet others, where the high index mechanical performance is well in control, a higher index ARC stack 49 may be desired. Fourth ARC sublayer 48 is perhaps the most critical ARC sublayer to optimize because it generally has a large index and material property mismatch with third ARC sublayer 47. In some embodiments it may be desired to minimize stress for improved adhesion. In some embodiments it may be desired to maximize hardness to reduce degradation of the scratch performance achieved by the rest of the stack 41. In some embodiments it may be desired to decrease index to 1.4 or lower to maximize anti-reflection capability. In all of these embodiments, the novel improved simultaneous combination of high hardness, high toughness, low stress and increased optical range provide advantageous performance.

With the above disclosure, an optical coating film is provided, comprising an oxynitride of a base cation material, the film having refractive index lower than 1.8, hardness greater than 18 GPa, and thickness above 500 nm but below 3 microns. In the film, the cation material may include silicon, aluminum or silicon and aluminum. The film may have density that is higher at the center depth-wise than towards the surface or towards both surfaces. As noted, these properties can be achieved by proper setting of clocking angle, anode aperture, substrate transport speed, gas flow rates and cathode power.

With the above disclosure, an optical coating film is provided, comprising an oxynitride of a base cation material, the film having: a refractive index between n=1.9 to n=2.05 and film layer hardness is greater than 20 GPa, a refractive index between n=1.8 to n=1.9 and film layer hardness is greater than 18 GPa, a refractive index between n=1.7 to n=1.8 and film layer hardness is greater than 15 GPa, a refractive index between n=1.6 to n=1.7 and film layer hardness is greater than 12 GPa, a refractive index between n=1.5 to n=1.6 and film layer hardness is greater than 10 GPa, and a refractive index between n=1.3 to n=1.5 and film layer hardness is greater than 6 GPa. As noted, these properties can be achieved by proper setting of clocking angle, anode aperture, substrate transport speed, gas flow rates and cathode power.

With the above disclosure, an optical coating film is provided, comprising an oxynitride of a base cation material, the film having: a refractive index between n=1.9 to n=2.05 and film layer hardness is greater than 22 GPa, a refractive index between n=1.8 to n=1.9 and film layer hardness is greater than 20 GPa, a refractive index between n=1.7 to n=1.8 and film layer hardness is greater than 17 GPa, a refractive index between n=1.6 to n=1.7 and film layer hardness is greater than 14 GPa, a refractive index between n=1.5 to n=1.6 and film layer hardness is greater than 12 GPa, and a refractive index between n=1.3 to n=1.5 and film layer hardness is greater than 8 GPa. As noted, these properties can be achieved by proper setting of clocking angle, anode aperture, substrate transport speed, gas flow rates and cathode power.

In the above films, the compressive stresses are below 300 MPa and even below 100 MPa. Also, the density in the film may be modulated through the thickness of the film.

A coated article is disclosed, the article comprising: a transparent substrate and a protective coating comprising: an adhesion layer formed over the substrate; a protective layer formed over the adhesion layer and may have refractive index of from 1.6 to 1.8; and an anti-reflective layer formed over the protective layer, the anti-reflective layer comprises a plurality of sublayers, wherein at least one sublayer has a refractive index higher than index of said protective layer and at least one sublayer has a refractive index lower than the index of said protective layer. The article may further comprise a stress relieving intermediate layer consisting of an oxide containing layer having refractive index n higher than index of the adhesion layer and lower than index of the protective layer. In the article, the adhesion layer may consist of an oxide containing layer having refractive index matching index of the transparent substrate. In the article, the protective layer may have a thickness at least three times greater than the adhesion layer and a refractive index higher than index of the substrate. In the article, at least one anti-reflective sublayer may have a refractive index below 1.46. In the article, the anti-reflective layer comprises three sublayers, a first sublayer abutting the protective layer has a refractive index higher than the protective layer, a second sublayer abutting the first sublayer has a refractive index higher than the first sublayer, and a third sublayer abutting the second sublayer has a refractive index lower than the protective layer. Alternatively, in the article, the anti-reflective layer comprises four sublayers, a first sublayer abutting the protective layer has a refractive index higher than the protective layer, a second sublayer abutting the first sublayer has a refractive index higher than the protective layer but lower than the first sublayer, a third sublayer abutting the second sublayer has a refractive index higher than the second sublayer, and a fourth sublayer abutting the third sublayer has a refractive index lower than the protective layer. Also, the transmittance through said protective coating and said substrate is higher than the transmittance through said substrate without said protective coating.

In the protective coating, at least one film layer comprises at least one of: a refractive index between n=1.9 to n=2.05 and film layer hardness is greater than 20 GPa, a refractive index between n=1.8 to n=1.9 and film layer hardness is greater than 18 GPa, a refractive index between n=1.7 to n=1.8 and film layer hardness is greater than 15 GPa, a refractive index between n=1.6 to n=1.7 and film layer hardness is greater than 12 GPa, a refractive index between n=1.5 to n=1.6 and film layer hardness is greater than 10 GPa, and a refractive index between n=1.3 to n=1.5 and film layer hardness is greater than 6 GPa. Alternatively, in the protective coating at least one film layer comprises at least one of: a refractive index between n=1.9 to n=2.05 and film layer hardness is greater than 22 GPa, a refractive index between n=1.8 to n=1.9 and film layer hardness is greater than 20 GPa, a refractive index between n=1.7 to n=1.8 and film layer hardness is greater than 17 GPa, a refractive index between n=1.6 to n=1.7 and film layer hardness is greater than 14 GPa, a refractive index between n=1.5 to n=1.6 and film layer hardness is greater than 12 GPa, and a refractive index between n=1.3 to n=1.5 and film layer hardness is greater than 8 GPa.

A method is disclosed for fabricating thin-film coating on substrates, comprising: in a first sputtering station having a pair of two rotating targets with a magnetron positioned within each target, orienting each of the magnetrons to a clocking angle of from 0° to +/−60° from vertical, wherein a zero clocking angle means vertical, a positive clocking angle indicates tilt towards center of the sputtering station and a negative clocking angle indicates tilt away from the center of the sputtering station; flowing sputtering gas and reactive gas between the two rotating targets; energizing the targets to rotate the targets; applying a bias potential to the magnetrons to ignite plasma between the rotating targets; continuously passing substrates inside the station under the targets to thereby coat the substrates with material sputtered from the targets. The method further comprises transporting the substrates to a second station having two pairs each of two rotating targets with a magnetron positioned within each target; orienting each of the magnetrons to a clocking angle of from 0° to +/−60° from vertical; flowing sputtering gas and reactive gas between the two rotating targets; energizing the targets to rotate the targets; applying a bias potential to the magnetrons to ignite plasma between the rotating targets; continuously passing substrates inside the station under the targets to thereby coat the substrates with material sputtered from the targets. In an embodiment of the method, the clocking angle in the second station is different from the clocking angle in the first sputtering station. In an embodiment of the method the substrates are transported in the first sputtering station forward and backwards at least once and transported in the second sputtering station only once in a forward direction only. In an embodiment of the method at least one pair of targets is operated in metal mode and at least one pair of targets is operated in poison mode. In an embodiment of the method the angle of approach of sputtered material to the target is limited by installing an anode aperture below the targets. In an embodiment of the method electrons are removed from the targets by providing an anode with an electron filter.

A method for coating transparent substrates with optical coating, the method comprising: flowing gas at a first rate in between a first pair of rotating sputtering targets and energizing the first pair of rotating sputtering targets at a first power level to maintain plasma between the first pair of rotating sputtering targets; transporting the substrates under the first pair of rotating sputtering targets in a repeated forward and reverse motions at a first speed to thereby deposit an adhesion layer of refractive index matching refractive index of the substrate, on the substrate; flowing gas at a second rate in between a second pair of rotating sputtering targets and energizing the second pair of rotating sputtering targets at a second power level to maintain plasma between the second pair of rotating sputtering targets; transporting the substrates under the second pair of rotating sputtering targets in a single forward motion at a second speed, slower than the first speed, to thereby deposit a protective layer of refractive index higher than refractive index of the substrate; flowing gas at a third rate in between a third pair of rotating sputtering targets and energizing the third pair of rotating sputtering targets at a third power level to maintain plasma between the third pair of rotating sputtering targets; and, transporting the substrates under the third pair of rotating sputtering targets in a repeated forward and reverse motions at a third speed to thereby deposit an anti-reflective layer over the protective layer. In the method, flowing gas at a third rate comprises changing the flow rate between forward and reverse motions of the substrates to thereby form the anti-reflective layer by depositing consecutive sub-layers having different refractive indices. In the method, energizing the third pair of rotating sputtering targets comprises changing power levels between forward and reverse motions of the substrates to thereby form the anti-reflective layer by depositing consecutive sub-layers having different refractive indices. In the method, flowing gas at a third rate, energizing at a third power level and transporting at a third speed are adjusted to form each sub-layer to be 10-150 nm thick. In the method, flowing gas at a second rate, energizing at a second power level and transporting at a second speed are adjusted to form the protective layer to be 500 nm to 2 micron thick. In the method, flowing gas at a first rate, energizing at a first power level and transporting at a first speed are adjusted to form the adhesion to be 50-250nm thick. In the method, transporting the substrates comprises placing a plurality of substrates on a substrate carrier and orienting at least two substrates at a different elevational orientation. In the method, orienting at least two substrates at a different elevational orientation comprises orienting substrates in middle of the carrier horizontally flat, and orienting substrates at a periphery of the substrate carrier at a tilt from the horizontal.

Generally, three different gases are flown into the chamber and the relative flow rates and the total flow rate may be used to control the characteristics of the final film. For example, the relative flow ratio between oxygen and nitrogen can be adjusted to control the refractive index, while the flow rate of the carrier gas, e.g., argon, can be adjusted to control the hardness of the film. Therefore, within the context of the claims, setting or changing a flow rate may refer to flow rate of one gas, several or all of the gases, or ratio of flow rates of two or more gasses. With this understanding, unless explicitly specified otherwise, the recited “first rate,” “second rate” and/or “third rate” may be the same or different from each other, and similarly, unless explicitly specified otherwise, the “first power level” the “second power level” and the “third power level” may be the same or different from each other.

While the disclosed embodiments are described in specific terms, other embodiments encompassing principles of the invention are also possible. Further, operations may be set forth in a particular order. The order, however, is but one example of the way that operations may be provided. Operations may be rearranged, modified, or eliminated in any particular implementation while still conforming to aspects of the invention.

All directional references (e.g., upper, lower, upward, downward, left, right, leftward, rightward, top, bottom, above, below, etc. are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. It is intended that all matter contained in the above description or shown in the accompanying drawings shall be interpreted as illustrative only and not limiting. Changes in detail or structure may be made without departing from the spirit of the invention as defined in the appended claims.

It must be noted that as used herein and in the appended claims, the singular forms “a”, “an”, and “the” include plural referents unless the context clearly dictates otherwise.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

What is claimed is:

1. An optical coating film is provided, comprising an oxynitride of a base cation material, the film having refractive index lower than 1.8, hardness greater than 18 GPa, and thickness above 500 nm but below 3 microns.

2. The optical coating film of claim 1, wherein the cation material includes silicon, aluminum or silicon and aluminum.

3. The optical coating film of claim 2, having a density that is higher at the center depth-wise than towards one surface or towards both surfaces.

4. The optical coating film of claim 2, having one of: a refractive index between n=1.9 to n=2.05 and film layer hardness greater than 20 GPa, a refractive index between n=1.8 to n=1.9 and film layer hardness greater than 18 GPa, a refractive index between n=1.7 to n=1.8 and film layer hardness greater than 15 GPa, a refractive index between n=1.6 to n=1.7 and film layer hardness greater than 12 GPa, a refractive index between n=1.5 to n=1.6 and film layer hardness greater than 10 GPa, and a refractive index between n=1.3 to n=1.5 and film layer hardness greater than 6 GPa.

5. The optical coating film of claim 3, having one of: a refractive index between n=1.9 to n=2.05 and film layer hardness is greater than 22 GPa, a refractive index between n=1.8 to n=1.9 and film layer hardness is greater than 20 GPa, a refractive index between n=1.7 to n=1.8 and film layer hardness is greater than 17 GPa, a refractive index between n=1.6 to n=1.7 and film layer hardness is greater than 14 GPa, a refractive index between n=1.5 to n=1.6 and film layer hardness is greater than 12 GPa, and a refractive index between n=1.3 to n=1.5 and film layer hardness is greater than 8 GPa.

6. The optical coating film of claim 2, having compressive stresses below 300 MPa.

7. The optical coating film of claim 3, having compressive stresses below 100 MPa.

8. The optical coating film of claim 2, having modulated density throughout film thickness.

9. A coated article comprising: a transparent substrate and a protective coating, the protective coating comprising an adhesion layer formed over the substrate; a protective layer formed over the adhesion layer having refractive index of from 1.6 to 1.8; and an anti-reflective layer formed over the protective layer, the anti-reflective layer comprises a plurality of sublayers, wherein at least one sublayer has a refractive index higher than index of said protective layer and at least one sublayer has a refractive index lower than the index of said protective layer.

10. The coated article of claim 9, further comprising a stress relieving intermediate layer consisting of an oxide containing layer having refractive index n higher than index of the adhesion layer and lower than index of the protective layer.

11. The coated article of claim 10, wherein the adhesion layer consists of an oxide containing layer having refractive index matching index of the transparent substrate.

12. The coated article of claim 10, wherein the protective layer has a thickness at least three times greater than the adhesion layer and a refractive index higher than index of the substrate.

13. The coated article of claim 9, wherein at least one anti-reflective sublayer may have a refractive index below 1.46.

14. The coated article of claim 9, wherein the anti-reflective layer comprises three sublayers, a first sublayer abutting the protective layer and has a refractive index higher than the protective layer, a second sublayer abutting the first sublayer and has a refractive index higher than the first sublayer, and a third sublayer abutting the second sublayer and has a refractive index lower than the protective layer.

15. The coated article of claim 9, wherein the anti-reflective layer comprises four sublayers, a first sublayer abutting the protective layer has a refractive index higher than the protective layer, a second sublayer abutting the first sublayer has a refractive index higher than the protective layer but lower than the first sublayer, a third sublayer abutting the second sublayer has a refractive index higher than the second sublayer, and a fourth sublayer abutting the third sublayer has a refractive index lower than the protective layer.

16. The coated article of claim 9, wherein optical transmittance through said protective coating and said substrate is higher than optical transmittance through said substrate without said protective coating.

17. The coated article of claim 9, wherein at least one layer of the protective coating has one of: a refractive index between n=1.9 to n=2.05 and film layer hardness is greater than 20 GPa, a refractive index between n=1.8 to n=1.9 and film layer hardness is greater than 18 GPa, a refractive index between n=1.7 to n=1.8 and film layer hardness is greater than 15 GPa, a refractive index between n=1.6 to n=1.7 and film layer hardness is greater than 12 GPa, a refractive index between n=1.5 to n=1.6 and film layer hardness is greater than 10 GPa, and a refractive index between n=1.3 to n=1.5 and film layer hardness is greater than 6 GPa.

18. The coated article of claim 9, wherein at least one layer of the protective coating has one of: a refractive index between n=1.9 to n=2.05 and film layer hardness is greater than 22 GPa, a refractive index between n=1.8 to n=1.9 and film layer hardness is greater than 20 GPa, a refractive index between n=1.7 to n=1.8 and film layer hardness is greater than 17 GPa, a refractive index between n=1.6 to n=1.7 and film layer hardness is greater than 14 GPa, a refractive index between n=1.5 to n=1.6 and film layer hardness is greater than 12 GPa, and a refractive index between n=1.3 to n=1.5 and film layer hardness is greater than 8 GPa.

19. The coated article of claim 9, wherein the protective layer has a hardness greater than 18 GPa.

20. The coated article of claim 9, wherein the protective layer has compressive film stress less than 100 MPa.
